(19) United States
(12) Patent Application Publication
(10) Pub. No.: US 2024/0320395 A1
(43) Pub. Date: Sep. 26, 2024

(54) IDENTIFYING PARAMETER MODIFICATIONS TO ENABLE INDUSTRIAL PROCESSES TO BECOME MORE TOLERANT TO CHANGES IN THE AVAILABILITY AND COMPOSITION OF MATERIALS

(71) Applicant: Friedrich-Alexander-Universität Erlangen-Nürnberg, Erlangen (DE)

(72) Inventors: Maximilian Hungsberg, Darmstadt (DE); Bastian Etzold, Erlangen (DE); Alfons Drochner, Darmstadt (DE)

(21) Appl. No.: 18/679,077

(22) Filed: May 30, 2024

Related U.S. Application Data
(63) Continuation of application No. PCT/EP2022/083059, filed on Nov. 23, 2022.

(30) Foreign Application Priority Data
Nov. 30, 2021 (EP) 21211475.5
Dec. 27, 2021 (EP) 21217840.4

(51) Int. Cl. G06F 30/20; G05B 15/02

(52) U.S. Cl. CPC G06F 30/20; G05B 15/02

(57) ABSTRACT

A computer-implemented method identifies an operation parameter of an industrial process as a candidate for modification so that the process can continue even of the material at the input of the process changes. In simulation instances, the computer receives representations of the material and of operation parameters and provides a representation of the would-be product. The computer classifies the instances into first and second quality classes. The computer continues by clustering—separated by parameters—the instances according to parameter attributes and according to the first and second quality classes. The computer repeats the simulation with variations that are related to significant differences, and identifies the candidate for modification.

### CROSS-REFERENCE TO RELATED APPLICATIONS

This application claims priority to, and is a continuation of, PCT/EP2022/083059, filed on Nov. 23, 2022 and entitled “IDENTIFYING PARAMETER MODIFICATIONS TO ENABLE INDUSTRIAL PROCESSES TO BECOME MORE TOLERANT TO CHANGES IN THE AVAILABILITY AND COMPOSITION OF MATERIALS,” which in turn claims priority to EP application Ser. No. 21/211,475.5 filed on Nov. 30, 2021 and also claims priority to EP application Ser. No. 21/217,840.4 filed on Dec. 27, 2021, all of which are hereby incorporated by reference in their entireties.

### TECHNICAL FIELD

In general, the disclosure relates to industrial production processes, and more in particular, the disclosure relates to computer systems, methods and computer-program products to make a particular production process more flexible to changes in the availability and composition of materials.

### BACKGROUND

Industrial systems perform processes such as production processes. From a high-level perspective, a particular industrial system comprises interacting components or units, such as for example, transport equipment, chemical reactors, industrial machines, measurement instruments, and the like.

An industrial process usually runs on a system that is specialized to the process. The system can only perform the process when specific conditions are complied with. For example, the systems may require materials to be available in pre-defined qualities and quantities.

Much simplified, the production process may start by the system taking in one or more (raw) materials, and the process may end by the system delivering one or more products. For example, a refinery takes in crude oil, moves it through a chain of reactors and delivers gasoline in different octane ratings. (Different ratings may correspond to different product categories and quality specifications.)

In many scenarios, the process comprises sequences of process steps, and the industrial system has system components—so-called “units”—that are specialized to the steps. To stay with the refinery example, a particular refinery system may be specialized in producing gasoline, but not in producing diesel. Despite such specialization, the units are adaptive to changes in the surrounding conditions, such as the changes in the material or changes in the energy supply. For example, the refinery system can still produce standard-compliant gasoline even if some chemical (or other) properties of the oil change. Or, a heater component within the refinery preferably operates when photovoltaic energy is available, and operates on other energy only occasionally.

However, tolerances to changing conditions are relatively narrow. Tolerances are related to intake conditions (such as material availability and composition), to supply conditions (such as energy availability), output conditions (the product to comply with pre-defined ratings), and others.

Further, some materials at the intake of the systems may not be available in sufficient amounts, at least temporarily. Consequently, the industrial system may not perform the pre-defined process, at least for the time being.

For example, it is desirable to replace fossil materials by alternative materials (from waste, from renewable sources, etc.). An existing process that runs on a particular system may be specialized to run with crude oil, coal or lignite (some of them occasionally not available), but the process may not run with plastic waste (that is available in relatively large quantities).

System operators may modify the industrial process and/or the industrial system, by replacing or modifying system components, by modifying the sequence of processing steps, or otherwise.

Depending on modification efforts, the skilled person uses different terminology: to “re-design” the process (and the system) in case the modifications require changes to system components, or to “adapt” the process in case the modifications require changes in the way the components are being controlled.

A re-design may not be possible in all situations, and re-design takes time. Further, a re-design may prevent the system to perform the original process. For example, a power plant may be re-designed from lignite to gas, but such a modified power plant can't use lignite any longer.

Adaptations may be applicable for some scenarios. System operators may run components in a slightly different way, substantially without changing the process. For example, a reactor may usually heat up an intermediate product to a particular temperature, but the operator may heat up the intermediate product to a higher temperature. The system can accommodate temporary unavailability of energy because the intermediate product stays hot enough.

There is a preference to adapt existing processes but to avoid re-design.

However, modifying the process and/or the system (by re-design or by adaptation) is not as easy as it appears. Usually there is no single parameter (such as a temperature) to adjust, and a modification at one component (e.g., to increase the temperature) may have an effect to a later process step (e.g., more time needed to cool down a substance).

There are constraints to identify suitable modifications, among the following: (i) Processes are complex and difficult to model by mathematical equations. Equations may be available only for some aspects. Even if available, some equations may lack an analytic solution, and solving them numerically requires to spend relatively large computing resources. (ii) Simulations result in a relatively high number of datasets, and it would take the computer relatively long time to identify potential parameter modification to be applied to the process. The identification may simply come too late so that effective modifications are difficult to implement.

Computers can process data in relatively large amounts (such as historical data from existing processes, “big data”) and can simulate processes, but the consumption of computing resources (e.g., in terms of calculation duration, hardware requirements) can not be neglected.

A production system for producing a product such as a chemical product may comprise a computer that simulates the production of the product under various conditions, and that presents an optimum production condition.

### SUMMARY

A computer system executes a computer-implemented method according to a computer-program product. The computer assists the system operator of an industrial system to identify at least one operation parameter. The parameter would have to be modified so that the industrial system can operate in an alternative phase in that it delivers a pre-defined product even if the availability of materials has changed compared to a standard phase.

In short, a computer-implemented method identifies an operation parameter of an industrial process as a candidate for modification so that the process can continue even if the material at the input of the process changes. In simulation instances, the computer receives representations of the material and of operation parameters and provides a representation of the would-be product. The computer classifies the simulation instances into first and second quality classes. The computer continues by clustering the simulation instances according to parameter attributes and according to the first and second quality classes. The computer applies clustering for parameters separately. The computer repeats the simulation with parameter variations that are related to significant differences in the product quality, and identifies the candidate for modification.

A computer-implemented method is provided to identify an operation parameter of an industrial process as a candidate for a parameter modification.

In a standard process phase, an industrial system, takes in standard material as a standard mixture of substances, performs activities of a pre-defined industrial process according to a plurality of operation parameters (referred to as the original operation parameter set hereinafter), and delivers a product, with the product having pre-defined properties (the pre-defined product hereinafter).

A computer uses a simulator module to simulate the industrial process by accessing a model that represents the system and that represents the industrial process. In each simulation instance, the simulator module receives a material tuple with elements, wherein the material tuple represents the material, and wherein its elements represent the substances of the material. In each simulation instance, the simulator module receives an operation parameter tuple with elements, wherein the operation parameter tuple represents the operation parameters set of the industrial process, and wherein its elements represent the individual operation parameters as well as represent their attributes. In each simulation instance, the simulator module provides a product tuple with elements, wherein the product tuple represents the product, and wherein its elements represent individual properties of the product.

The computer uses a variator module for varying the material tuple and to vary the operation parameter tuple and to provide tuple variations to the simulator module for performing multiple simulations. The computer uses an instance classifier module for classifying simulation instances into first class instances that provide product tuples representing products that would be pre-defined products, and second class instances otherwise. The computer uses an evaluator module for clustering the instances according to attributes of the operation parameter elements and according to the first or second class instances, resulting—for operation parameters separately—in a first cluster with first class instances and with a first attribute range, and in a second cluster for the other instances otherwise, and with a second attribute range. The computer uses the evaluator module for identifying at least two parameters values for that the first and second clusters differ with statistical significance. The computer uses the variator module and the simulator module for repeating the simulation with variations, and identifies the candidate for modification as the at least one parameter that for the simulation represents an alternative process phase of the industrial system that takes in material as an alternative mixture of substances, performs activities of the pre-defined industrial process according to an alternative operation parameter set, and delivers the pre-defined product.

Optionally, the evaluator module performs the identifying step with detecting that the first and the second clusters differ significantly by applying metrics, selected from: cross-referencing, t-testing (or t-test).

Optionally, the evaluator module determines if the at least two parameter values represent parameters that are related in the industrial system.

Optionally, the evaluator module performs the determining step by interacting with a simulation user that is the user of the computer.

Optionally, the tuple variator module comprises a material tuple variator module that generates a material variation set by processing historical data to identify value ranges with boundaries for the shares of the substances in the mixture; and varying elements of the material tuples within boundary elements that correspond to the boundaries.

Optionally, the material tuple variator module generates the material variation set by processing historical data for historical material variations, wherein particular substances are represented by intervals with minimum and maximum quantities.

Optionally, the material tuple variator module generates the material variation set by generating intermediate values within the intervals, with a value spacing that is larger than the value spacing of the material.

Optionally, the variator tuple module comprises an operation parameter tuple variator that varies parameter elements for the simulation according to a modification feasibility of the operation parameters.

Optionally, the modification feasibility of the operation parameters corresponds to a likelihood by that the candidate for modification can actually turn the original parameter set to the alternative operation parameter set.

Optionally, the computer uses the instance classifier module for classifying simulation instances into first and second class instances by applying further criteria, such as process related criteria.

From a different perspective, a computer program product is provided that, when loaded into a memory of a computer system and executed by at least one processor of the computer system, causes the computer system to perform the steps of the computer-implemented method. A computer system comprises a plurality of function modules which, when executed by the computer system, perform the steps of the computer-implemented method.

### BRIEF DESCRIPTION OF THE DRAWINGS

FIG. 1 illustrates an industrial system that performs an industrial process, and illustrates a computer that simulates the process;

FIG. 2 illustrates process phases and phase transitions, in a status diagram;

FIG. 3 repeats the status diagram, but adds a further classification of the phases;

FIG. 4 illustrates the process running on the system in different scenarios;

FIG. 5 illustrates a flow-chart diagram of a computer-implemented method to identify the operation parameter of an industrial process as a candidate for modification;

FIG. 6 illustrates a tracking list by that an evaluator module of the computer keeps track of simulation instances;

FIG. 7 illustrates a status-diagram to show simulation and other activities;

FIG. 8 illustrates simplified histograms of historical material mixtures, as the basis for the computer to generate variants;

FIG. 9 illustrates the clustering of simulation instances for selected parameters, with clustering according to attribute values and to instance classes;

FIGS. 10 and 11 illustrate the clustering of FIG. 9 with further detail, and

FIG. 12 shows a generic computer system.

### DETAILED DESCRIPTION

### Overview

From a high-level perspective, an industrial system takes in material (or “receives” material), performs activities of a pre-defined industrial process according to a plurality of operation parameters (in short “parameter set”), and delivers a product.

From that perspective, the material is a mixture (or composition) of substances. As the material availability can change in many real-world situations, the material can change in its composition. The material can be standard material (or quasi-standard material), alternative material, or off-range material.

The product can be a mixture of substances, and the properties can be defined by the share of the substances in that mixture. The product is either a product that has pre-defined properties (a “pre-defined product” in short), or a product that fails to have the pre-defined properties in at least one property (an “off-product” in short).

This division is convenient for explanation, and as used herein, (quasi) standard and alternative material leads to the pre-defined product, but off-range material does not.

Staying at that perspective level, there are two extreme cases to differentiate. First, in a standard phase, the system takes in standard material (i.e., a standard mixture of substances) and delivers the pre-defined product. In a quasi-standard phase, the system takes in quasi-standard material (slightly different from standard) but still delivers the pre-defined product. The term “standard” usually refers to particular industrial systems: one system has a different standard than a similar system. Second, in an off-range phase, the system takes in off-range material and delivers an off-product.

Operating the system in the (quasi) standard phase is desired but not always possible; and operating the system in the off-range phase should be avoided, or should be reduced to phases with relatively short durations. Between the extreme cases, there are other phases.

The parameter set for the standard phase (and also for the quasi-standard phase) is the original parameter set (that has been identified empirically over time). In other words, the original parameter set is suitable for the (quasi) standard material.

In an alternative phase, the industrial system takes in alternative material, performs the activities of the pre-defined industrial process according an alternative parameter set, but still delivers the product that has the pre-defined properties. A parameter set is “alternative to the original parameter set” if at least one operation parameter has been modified. Depending on different alternative materials, there can be different alternative phases.

In other words, there are alternative parameters (i.e., in the alternative parameter set) that are suitable to particular alternative materials. There is-however-no parameter set (original parameter set, or any alternative parameter set) that would be suitable to the off-range material.

Process phase transitions from (quasi)-standard to an alternative phase are enabled by modifying the parameter set (i.e., by at least one parameter, from original to alternative). Phase transitions in the opposite directions are enabled be returning to the original parameter set.

The adaptability of the industrial system to take in standard material (or quasi-standard material) and to provide the pre-defined product can be considered as a system-inherent material-tolerance (or tolerance provided by the original parameter set). However, such tolerance might be relatively narrow (and not suitable for many real-world situations).

In contrast, the adaptability of the industrial system to take in alternative material but to provide the pre-defined product can be considered as system-alternative material-tolerance.

Further, as the wording suggests, quasi-standard material is relatively similar to standard material, and alternative material is relatively different from (quasi) standard material.

From a different perspective, the off-range material range should be as small as possible, or in terms of material-availability and system operability, the duration of off-range intake should be as short as possible.

But leaving the high-level perspective and looking at the system operator, they face some challenges.

System operators can determine the share of the substances (e.g., by measuring, or by reading data that accompanies the material). The operators will recognize when the material qualifies as (quasi) standard material. But the operators may not know if the material also qualifies as alternative material (pre-defined product possible) or qualifies as off-range material (only off-product possible).

Qualifying material as being alternative material is possible under the condition that a suitable alternative parameter set can be identified (and is actually applied to the system). The system operator may know the share of the substances, but the system operator may not know whether the system can process the material such that the product is the pre-defined product. There is a dilemma. The system operator does not know if modifying parameters would allow the use of alternative material (for an alternative phase), or if the system would operate off-range (with or without parameter changes).

In other words, the system may turn to a “question phase” in that it does not take in (quasi) standard material, alternative material, or off-material, but takes in “question material” so that it delivers the off-product (at least most of the time), and for the system operator the product quality appears to be at random. The term “question” is convenient for explanation and expresses uncertainty that the operators may experience.

The operators could turn the question phase to an alternative phase (to have the pre-defined product) but the system operator does not know which parameter(s) to modify. Consequently, the operator may decide to “stop” the system until material becomes available in other mixtures.

The computer steps in here to assist the operators, simplified, by identifying at least one operation parameter to modify. The operation parameter would have to be modified indeed so that the industrial system can operate in an alternative phase.

Identification comprises the selection of a particular parameter within the original parameter set, and the indication of the parameter attribute to that the parameter needs to be set. If identified, but not actually modified, such an operation parameter is called “candidate for modification”.

As used herein, parameter modifications are explained with reference to the standard phase, but during real-world transitions (for example, between different alternative phases), the modifications are done accordingly.

Optionally, the computer can assist system operators to identify material that is quasi-standard material.

The computer represents the material, the operation parameters, and the product by numeric values in tuples. Material tuples represent the material, and the elements of the material tuples represent the substances of the material. Operation parameter tuples represent the plurality of operation parameters of the industrial process, and the elements of the operation parameter tuple represent the individual parameters. Product tuples represent the product, and the elements of the product tuple represent individual properties of the product, such as optionally, substances within the product.

The computer uses a simulator module to simulate the industrial process by accessing a model that represents the system and the process. In each simulation instance, the simulator module receives a particular material tuple, receives a particular operation parameter tuple, and provides a particular product tuple.

The simulator module performs simulation in multiple instances, and the simulator module can receive the tuples in variants. In other words, simulation instances are different if the variants of the material tuples are different, and/or if the variants of the operation parameter tuples are different.

Material tuples in variants (of the elements) can be considered as a material variation set {x}. Likewise, operation parameter tuples in variants (of the elements, and/or attributes) can be considered as an operation parameter variation set {y}.

The computer does not have to simulate the standard phase, because the standard material and the original parameters are known to result in the pre-defined product. If—optionally—the computer simulates the process under standard conditions, standard material is represented by the standard material tuple, and the original parameter set is represented by the original operation parameter tuple. Some of the material tuple variants correspond to quasi-standard materials, to alternative materials, or to off-range materials.

However, initially such correspondences are not known. Prior to simulation, most of the material tuples rather correspond to the “question material” and the simulation (with subsequent steps such as clustering) tells the operators if particular tuple variants can correspond to quasi-standard materials (no need to change operation parameters), to alternative materials (useful if the candidate parameter(s) are applied), or to off-range materials (where parameter modifications do not help).

Likewise, some of the operation parameter tuple variants correspond to alternative parameter sets, but again that is not yet known a priori. Some of the operation parameter tuple variants may represent a suitable alternative parameter set (that would transit a phase to an alternative phase, with the pre-defined product), may represent a parameter set for that the industrial system would deliver off-product (useful information for the operators not to set the parameters in that way), or may represent a parameter set that may be suitable as alternative parameter set (pre-defined product expected) depending on the material.

The simulator performs multiple simulations, but with the material variation set {x} and the operation parameter variation set {y} having less set members than theoretically possible, thus saving computation and other resources.

To optimize the number of simulations, the computer (with the simulator and the modules that interact with the simulator) classifies the instances (first/second class according to product quality and/or according to further criteria), and subsequently clusters the instances individually (not the operation parameter tuples as a whole).

For each of the multiple simulation instance, a classifier module differentiates the product tuples into first class product tuples that represent pre-defined products, and second class product tuples that represent off-products.

For convenience, the classification can be applied to the instances as well, first and second class instance (i.e., instances classified as “first class” or classified as “second class”). This classification looks at the output (of the process as simulated), but the operator is confronted with changing material availability (at the process intake).

First class instances (in the simulation) can correspond to the standard phase (of the process) if the material tuples represent standard material, to the quasi-standard phase if the material tuples represent quasi-standard material, or to an alternative phase.

However, stopping the simulation (and indicating corresponding material and alternative parameter set) may not be suitable because the material may not be available (in real-world) and the parameter may not be modifiable accordingly.

Second class instances can correspond to the off-range phase (because of the material), or to a phase that could turn into an alternative phase (of the operation parameter could be modified).

In other words, there are two directions to identify alternative parameter sets (that would enable the system to operate in an alternative phase).

The number of variants in both the material variation set {x} and the operation parameter variation set {y} is larger than the number of substances (in the material) and the number of operation parameters. Theoretical numbers are relatively high.

To keep the resource computation low, the computer can use the variations according to occurrence likelihoods (or feasibility) of their real-world counterparts.

Material parameter variations are related to possible practical use case scenarios. Simplified, some mixtures are unlikely to occur in real-world scenarios so that the variations with corresponding material tuples can be ignored.

Operational parameter variations are selected according to modification feasibility. Simplified, the feasibility increases with the likelihood that the operator can actually change a particular parameter. The computer identifies (one or more) parameters as candidates for being modified, and the operator decides to actually modify the parameter or not.

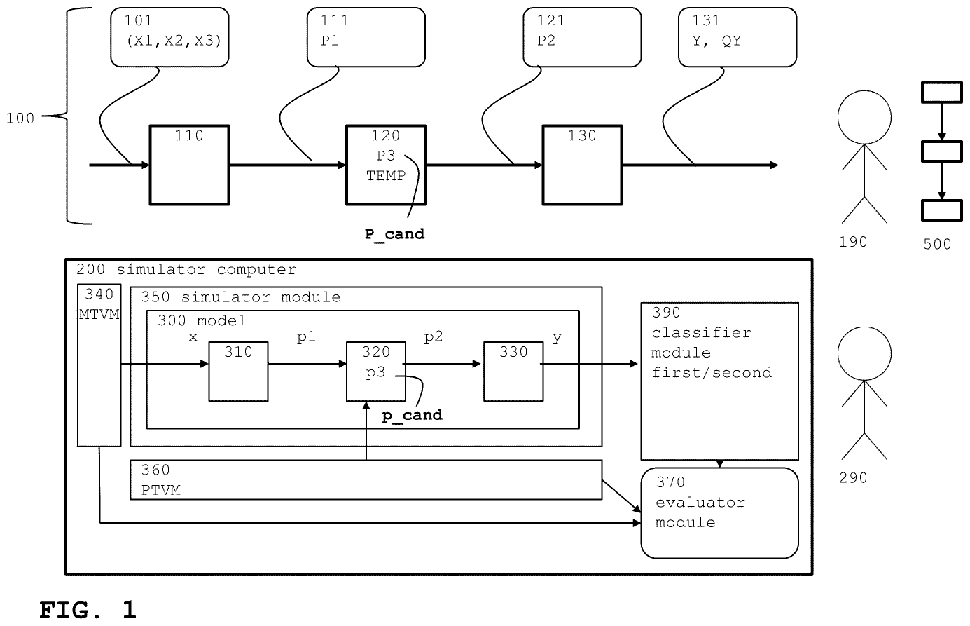

FIG. 1 illustrates industrial system 100 that is adapted to perform industrial process 500 (above), and illustrates simulator computer 200 (or “computer” in short) that is adapted to simulate process 500 (below) by having functional modules 340, 350, 360, 370 and 390.

This above/below separation is convenient for illustration, and the description refers to the correspondence between system and computer by using expressions in pairs such as, for example: system, process (and material flow) corresponding to model, process phase corresponding to simulation instance (i.e., phase to instance), substance corresponding to element, uppercase acronyms to lowercase acronyms (e.g., X/x, P/p, Y/y, QY/qy), indicator to indicator value, attribute to attribute value, system operator to simulator operator.

To keep the wording simple, the description occasionally aligns the wording. For example, system 100 operates with “direct parameters” and simulator computer 200 represents them by “direct elements” that is short for “elements that represent direct parameters”. Or, for example, system 100 may operate in an “alternative phase”, and simulator computer 200 represents this as an “alternative instance”.

Further, the description occasionally describes the simulation by omitting words, for example, “varying a parameter attribute” stands for the computer varying the data structure that represents a parameter attribute that would have to be varied in the (real) system.

Despite the separation in the description there is a potential interaction in real implementations. As used herein, a phrase like “simulate a process” is a short form for simulator computer 200 simulating process 500 as if it would run on system 100. The wording “would” symbolizes that the simulation results in candidates, such as candidate parameters (or candidate materials). “Would” also symbolizes that simulation results do not necessarily modify the system automatically. The simulation gives the system operator a view to the technical status of the system (and the opportunity to modify an operation parameters).

The notation “according to a plurality of operation parameters” or simplified “according to the parameter set” comprises that at least a subset of the parameters can be set by the system operator. The parameter set may comprise operation parameters that may change during the operation of system 100, caused by the system but without influence by the operator.

The notation “repeat a simulation” or the like is short for executing (or performing) the simulation in multiple instances. It does not matter if simulator computer 200 uses a single simulator module to processes the instances one after another (serial processing), or if simulator computer 200 uses multiple modules in parallel.

### Process and Industrial System

Industrial system 100 comprises technical equipment. The figure symbolizes the equipment by squares and by lines, and gives examples by operation units 110, 120, 130 (“units” in short) and connectors 101, 111, 121 and 131. Real-world systems have components in usually much higher numbers. For convenience, the figure also illustrates the role of system operator 190 who can interact with system 100. Although the figure illustrates system operator 190 as a human, system 100 can be operate automatically and/or operate remotely-controlled.

Units 110, 120, 130 can be reactors (to enable chemical reactions), heaters, coolers, heat exchangers, mixers or others. Units 110, 120, 130 have one or more inputs (or intakes) and one or more outputs (or outlet openings).

More in detail, the figure illustrates connector 101 (to transport material X to an input of unit 110), connector 111 (to transport intermediate product P1 from an output of unit 110 to an input of unit 120), connector 121 (intermediate product P2 to unit 130), and connector 131 (product Y to leave the system).

The connectors can be pipelines, vehicles or other means to enable material flow through the system. Linear equipment arrangement is convenient for explanation, but industrial systems usually comprise much more equipment in more complex interaction.

FIG. 1 also illustrates an example for industrial process 500, here simplified as a step sequence or activity sequence. The figure symbolizes process 500 by a flowchart next to system operator 190. Performing steps or activities in parallel is possible as well. The description refers to process 500 in a simplified and fictitious example with activities such as: receiving material X in a first unit to obtain intermediate product P1 (by a particular chemical reaction or the like), heating up intermediate product P1 in a second unit (e.g., to a particular temperature P3=1.000° C.), to obtain intermediate product P2, and processing intermediate product P2 in a third unit for a particular duration to obtain product Y.

Industrial process 500 runs on industrial system 100, but could also run on a similar system (provided to have suitable equipment).

The description uses the terms “material”, and “(intermediate) product” as convenient pointers to the material flow through the system. In the figure, a flow direction goes from left to right, from input to output. More realistic systems may have the flow in further directions. It does not matter if the flow goes with solids, liquids, or gasses, the aggregate state is not relevant.

Materials and (intermediate) products can be mixtures (or compositions) from different ingredients or substances. For example, material X can stand for a mixture of substances X1, X2, and X3. The description uses the tuple notation X=(X1, X2, X3) with tuple elements X1, X2, and X3.

The skilled person can differentiate materials and (intermediate) products according to different granularity levels, here called “granularity layer”. The description refers to such layers by way of example only: (layer 1). The substances can be organic substances (e.g., X1) or non-organic substances (e.g., X2), can be water-soluble or not, and so on (layer 2). The substances can be compounds in groups with similar chemical properties. The skilled person is familiar with acronyms, such as PET, PP, PE, PS, PVC, PMMA and others. This layer is also convenient, to differentiate, for example, gasoline, diesel, water, etc. (layer 3). There is a molecular differentiation, and the substances in the mixture could be identified as, for example, X1 being ethanol C₂H₅OH, X2 being methanol CH₄O, X3 being water H₂O), or otherwise. (layer 4). There are about 100 chemical elements, and the mixture could be identified by the chemical elements. The index could correspond to the atomic number in the periodic table. Of course, the skilled person does not have to consider all elements.

The layers are technical layers for that simulator computer 200 has appropriate simulation software that take the physico-chemical properties of the substances into account. For example, in layer 2, simulator computer 200 is able to differentiate PET from PP. Depending on the granularity layers, a particular material or product may qualify as mixture or not: for example, it can be PET (i.e., not mixture in layer 2, but a substance) or can be the mixture according to its elemental composition (layers 3, 4).

System operator 190 is familiar with specifying substances in terms of quality and quantity (e.g., differentiating substances in absolute or relative amounts of mass, volume, etc.).

In the fictitious example of this description, material X should be specified by mass percentages, such as 50% of substance X1, 30% of substance X2 and 20% of substance X3, alternatively noted as X=(50, 30, 20). The substances should substantially belong to the same granularity layer.

The number of K=3 substances as well as the percentages are convenient simplifications. The skilled person can apply the example to more complex mixtures.

The same principle applies to intermediate products P1, P2 (being also “operation parameters”, details below), and to product Y. Intermediate products P1, P2 and product Y can be mixtures as well. For example, product Y could be a mixture (Y1, Y2), for example Y=(gasoline, water). The skilled person can apply the notation for real mixtures, and for other granularity layers. In some scenarios, the ratio Y1/(Y1+Y2) can be considered as the yield of the process, especially in situations where Y2 would be a non-desired by-product (such as the water).

The description of industrial system 100 that performs industrial process 500 can stop here, because systems and processes are well-known. The skilled person can consult relevant text books for further information.

In view of the above example, system 100 can correspond (at least with some of its units) to the refinery that performs a known process with the input material X being crude oil and the product Y being gasoline, and of course, system 100 corresponds to the many other existing system, or to systems that are being planned.

### Parameters

As used herein, a parameter is any characteristic that is related to industrial process 500 or related to industrial system 100 and that may influence the operation of the system or the performance of the process. In other words, a characteristic has two requirements to be a parameter: its relation (to the process and/or to the system), and its influence (to the process and/or to the system).

Usually, system 100 has technical means to represent (and or the change) parameters. For convenience, it can be assumed that such means are implemented by one or more system computers. Using system computer is not mandatory, for example, a parameter can be modified manually. No matter if computers are involved or not, parameters have parameter attributes, and system 100 represents the parameter attributes by numerical values, by characters, by identifiers or the like.

The parameter attributes have attribute ranges, such as, for example, min-max ranges, binary ranges, sets of possible identification terms, or the like. Ranges can be distinct, or can be contiguous. Range with distinct values usually have a value spacing.

Parameters, parameter attributes, attribute ranges are further explained by way of example: (1) The identification of material X is a parameter, with attributes such as, for example, differentiate “carbon” from “crude oil”. (2) The identification of intermediate products (such as P1, P2), has attributes such as CO₂, CO, etc. (3) The mass or the volume of substances that go into a unit as material or that leave a unit (e.g., P1, P2, Y), is conveniently given by percentages. Particular are attributes are given as, for example X=(50, 30, 20), and ranges can be, for example, X=(10 . . . 70, 20 . . . 50, 10 . . . 30). An exemplary value spacing can be “one” (e.g., to differentiate 10 from 11). (4) Temperatures within the units (e.g., P3 being the target temperature of unit 120 when it processes Y1 to Y2) have attributes, such as 1.000° C., in ranges, such as between 1.000° C. and 2.000° C. The value spacing corresponds to measurement and control accuracy, and temperatures may be measured and/or controlled by 10° C. spacing. (5) The dimension of the units (for example, a maximum tank volume to receive a liquid or a gas) is a parameter, and the particular size is the attribute. The value spacing can correspond to measurement units, such as liters or meters. (6) The type of connectors is a parameter, such as steel pipelines or robot vehicles, and specified diameters, particular load capability to transport substances or the like are attributes. (7) The color of material and (intermediate) products is a parameter, with red, green, blue being attributes. (8) The status of a unit is a parameter, and attribute are, for example, “heating up” and “cooling down”.

The list is not complete, and the description will refer to further examples below.

There are also characteristics that are not considered to be parameters. For example, a unit may be painted at its outside in a particular color. But it does not matter if the unit is yellow or blue, the paint color does not influence the process or the system. Also, characteristics of product Y are not considered to be parameters (because the product is the result of the process).

Parameters can be material parameters and operation parameters. Material parameters are related to the material (here material X). Material parameters influence the operation of system 100 or performance of process 500 in the sense that a particular material in a certain amount is required to obtain a particular pre-defined product. Operation parameters are all other parameters.

The description uses this binary terminology (“material” and “operation”) because system operator 190 is confronted with conflicting constraints. System operator 190 potentially faces material X with unusual substance ratios (e.g., X≠(50, 30, 20)). System operator 190 may use material X that is similar (quasi-standard material), but system operator 190 may have limited possibilities to select the material. On the other hand, system operator 190 may be able to change one or more operation parameters.

Some parameters can influence other parameters. For example, the heating value or the calorific value of a substance that participates in a reaction is a first parameter, but there is an influence to the temperature that is reached during the reaction, being a second parameter. Such intra-parameter influences are also discussed in terms of direct and indirect parameters.

The description simplified and assumes the overall number K+N of parameters in system 100 as the sum of K material parameters and N operation parameters.

K can be related to the above-introduced granularity layer, and K can be relatively low (compared to N). In the fictitious example, the number K of input parameters is K=3 (substances in the example X1, X2, X3). In scenarios, at the element granularity (layer 4), K corresponds to the number chemical elements that occur in the mixture, K=7 for X=(C, H, O, N, S, Cl) or X=(carbon, hydrogen, oxygen, nitrogen, sulfur, chlorine). The skilled person can decide to take other elements or substances into account, such as for example, to consider inorganic substances in waste material that the process would turn into ashes.

The number N of operation parameters is relatively high (compared to K). The description collectively calls the parameters the “plurality of operation parameters”, or the “parameter set”, but keeps an example with N=3 operation parameters, occasionally, with N=10. In real scenarios, N could reach 1.000 or even 10.000.

FIG. 1 illustrates the parameter set P=(P1, P2, P3) by way of example. Operation parameters P1 and P2 identify intermediate products (that can be mixtures of different substances, with sub-parameters). Operation parameter P3 could be the target temperature in unit 120.

While the material X and the product Y can be mixtures, the operation parameters occur in the plurality (i.e., in the parameter set). Practically, there is no industrial system having only a single operation parameter. The description therefore applies the tuple notation to operation parameters as well, with parameter set P=(P1, P2, P3) in the example of FIG. 1 or P=(P1, . . . , Pn, . . . , PN) in general (n being the operation parameter index).

In view of the above discussion with phases, system operator 190 would have to modify at least one of the operation parameters to let the system operate in an alternative phase. However, further technical constraints need to be considered.

### Parameter Complexity

Due to the interaction of equipment (units, connectors etc.) in system 100 with each other, parameters may change during the operation of system 100. To stay with FIG. 1, intermediate products P1 and P2 may be available in varying quantities: unit 110 may discharge P1 to unit 120, so that the parameters that describe the amounts do change. Much simplified, units 100 gets empty, and unit 120 gets full. Or, the temperature of unit 120 may change when intermediate product P2 arrives.

From the view point of system operator 190, the operation parameters P=(P1, P2, P3, . . . . PN) can be differentiated into operation parameters that system operator 190 can directly modify, or “direct parameters”, and operation parameters that system operator 190 can not directly modify, or “indirect parameters”.

The ability to modify direct parameters depends on a variety of circumstances that are discussed below. For example, system operator 190 may set the target temperature of a heater (i.e., direct parameter), but may not set the temperature of a reaction or the temperature inside a unit (i.e., indirect parameters). System operator 190 may influence an indirect parameter by setting a direct parameter that is functionally related to the indirect parameters. For example, system operator 190 may influence the temperature in the reactor (indirect parameter) by controlling the mass of the substances inside the reactor (direct parameter).

For example, operation parameter P3 stands for the target temperature of unit 120 (during operation), it is therefore a direct parameter. The actual temperature (e.g., parameter P8) is a measurement value and therefore an indirect parameter. Using control loops for heater or the like is well-known, and the time-constant for the loop would be a further parameter P9. In case that system operator 190 can influence P8 (by controlling substances), the parameter P9 would be an indirect parameter.

As a side-note, the description does not apply the direct/indirect distinction to the material parameters, because system operator 190 is assumed to have no influence in choosing the material.

There is a further aspect that adds complexity. Although a parameter may qualify as a direct parameter, a modification may not have a sufficient effect on the process.

As explained above, system operator 190 may modify (one or more) operation parameters so that technical system 100 can operate in an alternative phase in that it delivers pre-defined products (as well). In many cases, system 100 will be a chemical system with some particulars to consider.

### Stationary Processes

There is a conceptual difference between industrial process 500 running on system 100 in general and its particular performance over time. From a high-level perspective, system 100 can perform process 500 continuously by substantially receiving material and providing products (usually running 24/7).

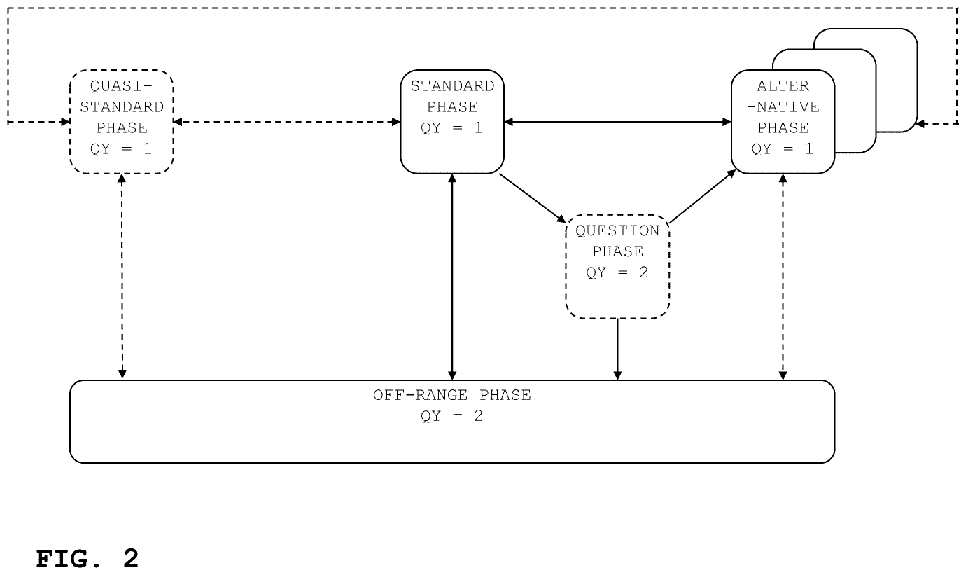

As process 500 is mainly a chemical process, the description uses the term “process phase” (or “phase” in short) to identify a time interval for that process 500 substantially runs as a stationary process. During so-called phase transitions, processes change from one stationary state to another stationary state (due to changes). In other words, the phase is the interval between the transitions. The duration of a transition state can be considered optionally. Transitions will be explained by way of example in connection with FIG. 2.

Every phase of process 500 can be different in the parameters (both in the material X and the parameter set P).

For example, there can be less or more material (in mass percentages) at the input, there can be variations in the temperatures or the like. The description identifies consecutive phases by indices (i)=(0), (2), . . . (I). The skilled person would collect data for each instance, such as by recording parameters to databases.

The description refers to separate phases for simplicity of explanation. However, the principle applies likewise: a change of the process can mark the start of a new phase. The concept of process phases is also applicable to systems that perform processes in so-called batches.

### Quality and Standard

As mentioned above, industrial processes usually run on specialized systems that need conditions to be complied with. It does not matter if a particular phase showed compliances for all conditions, but in any case, the product Y must comply with a pre-defined specification. Otherwise, the product Y can not be used (for its specified purpose).

System operator 190 (or a specialized component of the system) should perform a quality check to assign a quality indicator QY to product Y. For simplicity of explanation, quality indicator QY can be a (binary) indicator that differentiates the product Y being the pre-defined product (i.e., that complies with the pre-defined specification, QY=1), and the product Y being an off-product (that does not to comply, QY=2). Quality indicator QY does not influence the process or the system. Therefore, QY is not considered to be a parameter.

In the above refinery example, the quality indicator QY could depend on the octane rating that the gasoline reaches (or not). In other words, the example relates the quality indicator to the yield of product Y.

By empirical observations, system operator 190 knows that running process 500 on system 100 with pre-defined material X and operation parameters P (pre-defined parameters that system operator 190 can influence, directly or indirectly) leads to product Y that is the pre-defined product (QY=1).

The pre-defined parameters are in consecutive phases, for example, the percentage X(0)=(50, 30, 20) being the “(gold) standard”, or within a plus-minus offset of two percent (quasi-standard), in runs with X(1)=(48, 30, 22), or with X(2)=(52, 28, 20). To name one of many operation parameters P3, the temperature of the units, such as P3(0)=P3(1)=P3 (2)=1.000° C., i.e., would be the same for all runs (0), (1) and (2).

By observing multiple phases (with different parameters), system operator 190 observes that parameter changes may lead to failures (QY=2). For example, system 100 has performed phase (3) with material percentage X(3)=(40, 30, 30) (i.e., a material parameter that has been changed) and the temperatures of the units P3(3)=1.000° C. (i.e., an operation parameter that is not changed to the other phases). In a further failure example, the material percentage corresponds to the standard (50, 30, 20) but the temperature was too low.

System operator 190 may also have the experience that some operation parameters do not matter (e.g., the operation parameter “the time to heat up”). However, system operator 190 does not volunteer to make experiments. Modifying parameters creates the risk that the phases will fail (QY=2). There is even the potential risk that at least some equipment of system 100 may be harmed.

It is also possible to define (product) quality with further detail, such as for example “compliance”, “partial compliance” (cf. factory second), or “no compliance”. The skilled person could use a notation like QY=1, QY=1.5, QY=2 or the like.

The notation of QY as binary (1 or 2) or quasi-binary (1, 1.5, 2) is convenient for explanation, but the skilled person can relate quality to different products, or can relate quality to different product consumers. QY can therefore be noted otherwise. For example, product Y could be a fuel for cars, but depending on quality definitions, the technical system may produce Y as fuel for aircraft. In both cases, the product must comply with a pre-defined specification, but the specifications can be consumer-specific (in this example, specific for use in cars, or specific for use in aircraft). The example with the octane ratings is applicable likewise, with different specifications for different vehicles.

Quality can be classified by other data. For example, even for QY=1, there can be phases that are out of normal. For example, a unit may have consumed electrical energy in excess about a pre-defined threshold, or a tank may have spilled over. Such observations would classify a unit (or other equipment) to be out of normal, and such observations can be used as parameter (due to the influence, energy or material spoiled).

The skilled person can assign an overall quality indicator (to the process) by defining one or more rules that take quality indicators of system components into account. Such a rule can be based on logical relations. For example, given here in pseudo-code: IF (QP1=1 AND QP2=1 AND QY=1) THEN Q_overall=1 ELSE Q overall=2.

FIG. 2 illustrates process phases and phase transitions, in a status diagram. The notation is convenient for explanation, but it is noted that real-world systems react to change in the material and to changes in the parameters, and deliver the product as pre-defined product (QY=1) or as off-product (QY=2), as the case may be.

During a standard phase, system 100 takes in material that is a mixture of substances that have pre-defined ranges (i.e., standard material), performs activities of process 500 (according to parameter set, with parameters within pre-defined attribute ranges, “original ranges”, “original parameter set”), and delivers the pre-defined product (cf. QY=1).

System 100 can turn its operation to the quasi-standard phase by taking in quasi-material (only slight differences to the standard). Operating in the standard phase and in the quasi-standard phase symbolizes that system 100 shows a system-inherent material-tolerance to relatively minor changes in the material. As the quasi-standard phase might not occur frequently, the figure illustrates it (and the transitions) by dashed lines.

System 100 can turn to an alternative phase (with at least one operation parameter modified, resulting in an alternative parameter set) in that it still delivers the pre-defined product (symbolized here by QY=1). The transition is driven by the material ceasing to be (quasi) standard material but becoming alternative material.

Operating system 100 during an alternative phase symbolizes the system-alternative material-tolerance, a tolerance to a relatively larger change in the material, enabled by the parameter modification.

The process phase in the upper line of FIG. 2 (quasi-standard phase, standard phase, alternative phase) can turn to an off-range phase (the material becoming off-material, with QY=2 as the consequence).

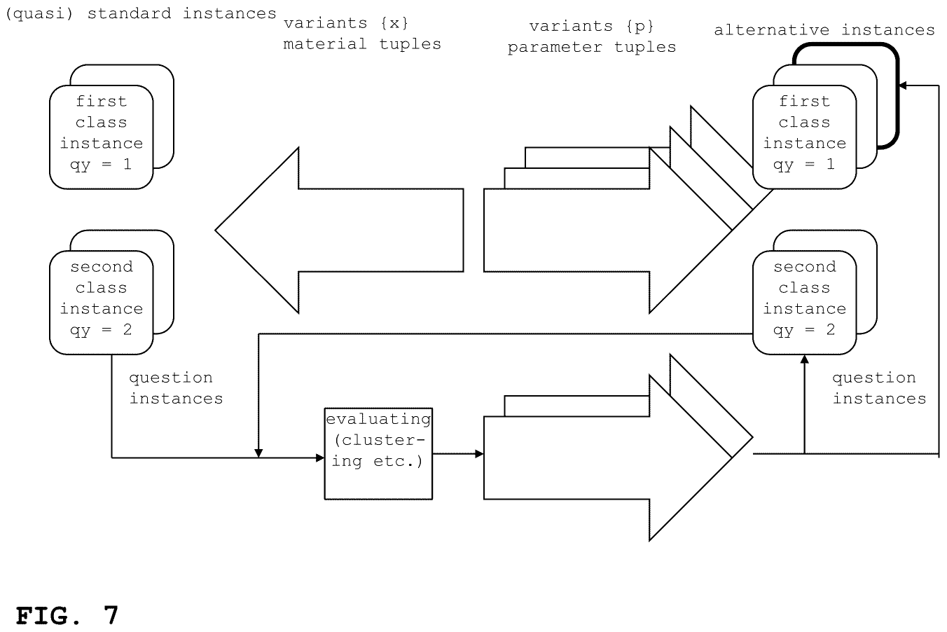

FIG. 2 has some analogy in FIG. 7 that focuses on simulation. The simulation tells system operator 190 when to expect what transition, so that system operator 190 can actually modify one or more operation parameters to enter the alternative phase.

FIG. 2 illustrates multiple alternative phases (by overlapping status symbols). There can be different alternative parameter sets that are suitable to different alternative materials.

FIG. 2 also symbolizes the question phase. System operator 190 may change the parameter set (to an alternative parameter set), to “rescue” the phase to become an alternative phase, but system operator 190 does not know which one. As the concept of the question phase is a convenient construct for explanation, the figure illustrates the question phase by dashed line.

In case of multiple product quality specifications, the differences would translate into different (quasi)-standard and alternative phases. In the above-mentioned car example, there would be different (quasi) standard phases and different alternative phases, for car fuel and for aircraft fuel.

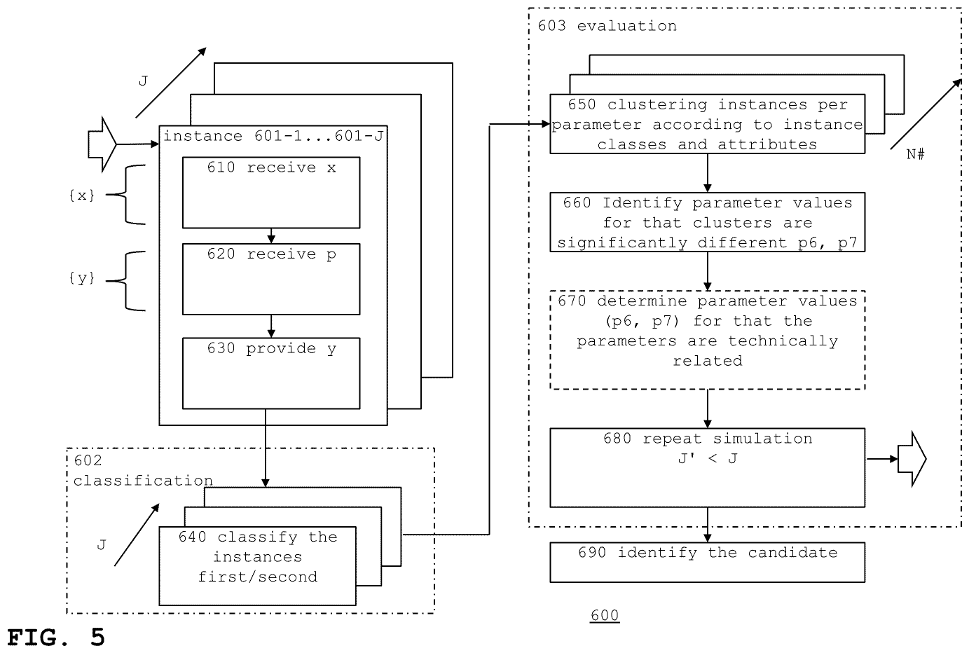

FIG. 2 does not illustrate the timing, but it is noted that a phase transition to a desired phase (such as to leave the question phase or the off-range phase to arrive at an alternative phase) requires the modification of a parameter. The time it takes the computer to identify one or more candidate parameters (for modification) roughly corresponds to the run-time of method 600 (FIG. 5), so that the run-time should be relatively short.

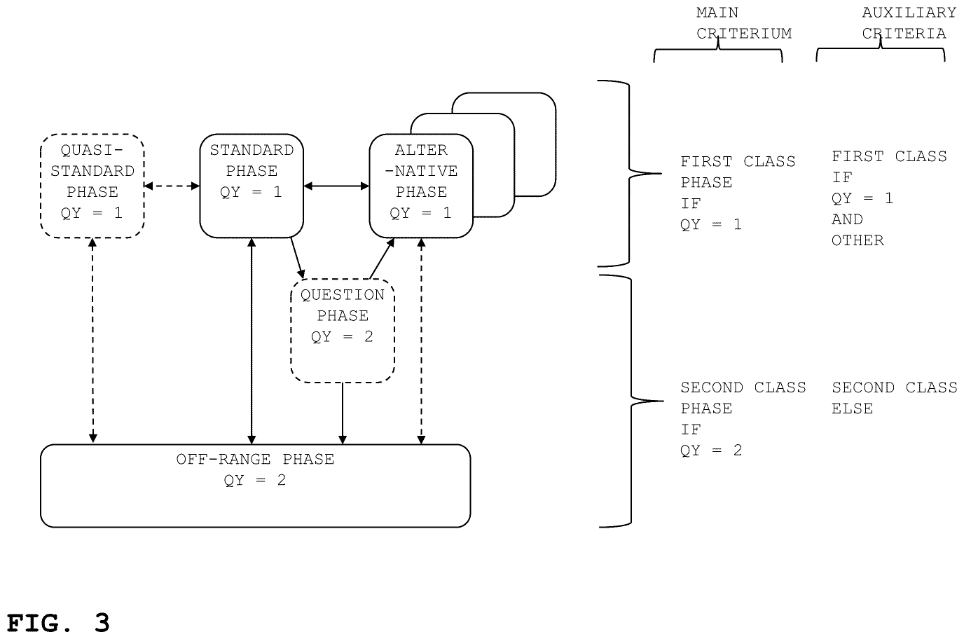

FIG. 3 repeats the status diagram with phases and phase transitions, but adds a further classification of the phases. Taking the quality of the product as the main criterium, the phases can be classified into first class phases for QY=1. In the notation of this description, (quasi) standard and alternative phases are first class phases). Second class phases lead to QY=2 (i.e, question phases, off-range phases). The description focuses on this main criterium.

Taking the quality of the process as auxiliary criteria, the phases can be classified into first class phases for QY=1 AND OTHER CONDITIONS and second class phases in all other situations (in the figure symbolized as ELSE). For example, the process may run as an alternative phase with QY=1, but with energy consumption that is above a pre-defined threshold (the other first class condition fails). Or, a failure occurs (such as a tank spilling over). System operator 190 may want to avoid that.

The phase classification serves as a so-called clustering dimension during simulation (by simulator computer 200). Since the skilled person determines quality (of products or of processes) almost on an every-day basis, the description does not have to give more details.

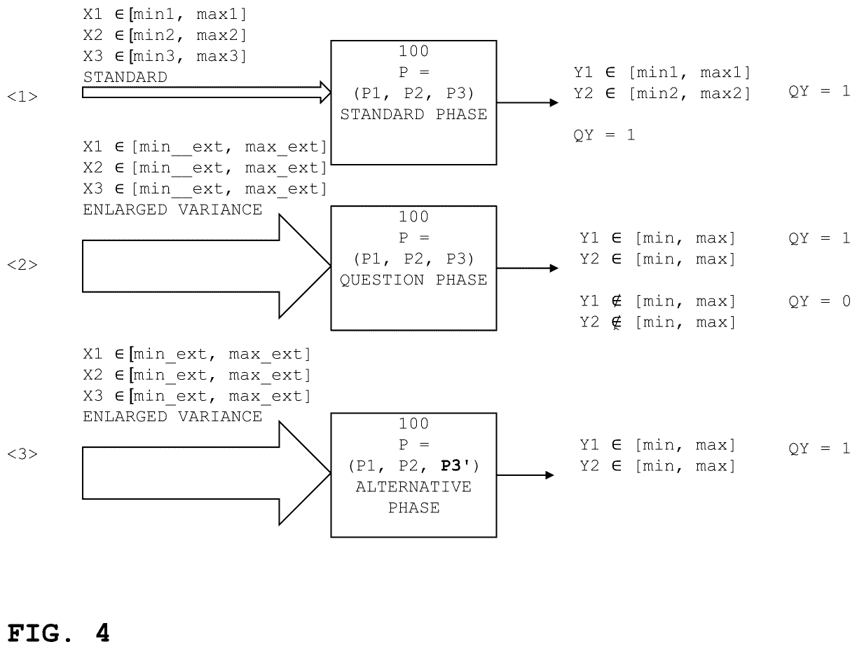

FIG. 4 illustrates the process (such as process 500 of FIG. 1) running on system 100 by a function from at least one material X=(X1, X2, X3) and one parameter set P=(P1, P2, P3) leading to at least one product Y (mixture of substances Y1, Y2). The figure shows different scenarios.

At the first glance, the notation for Y being a function of X and P appears justified, but process 500 is usually more complex. There are many cause-effect-relations (for example, between parameters) so that the process usually would not be mirrored by a matrix.

Scenario <1> indicates the standard phase. The substances X1, X2, X3 (of material X) are elements in pre-defined attribute ranges [min, max]. The ranges are given in one dimension as closed intervals, different for each substance. For the above example, the ranges are X=([48, 52], [28, 32], [18, 22]). The original parameter set P corresponds to the parameter that system operator 190 has obtained empirically. The product Y complies with the specifications because it has pre-defined properties. It is the pre-defined product. The figure symbolizes pre-defined properties assuming the product Y to be a mixture and by differentiating substances Y1 and Y2 of product Y to be within [min, max] as well. The quality indicator would be QY=1, if both substances are within the limits.

Scenario <2> indicates a change to the question phase. However, the process is not tolerant to material changes. Material X=(X1, X2, X3) has attributes in an extended range [min_ext, max_ext]. The original parameter set P=(P1, P2, P3) remains unchanged. The product Y would comply with the specifications only for X∈[min, max], for X1, X2 and X3 separately, leading to QY=1. However, but for the rest of the material range, the product would not have the pre-defined properties (at least with one of its substances, cf. the notation ∉[min, max]), leading to QY=2. In other words, scenario <2> shows uncertainty if system 100 provides the product Y as the pre-defined product or not.

System operator 190 may still decide to run the process in such scenario <2>, but would have to apply further measures (such as to discard product Y for QY=0). For chemical processes in continuous operation, it may be necessary to continue the process, even if QY=0 for some time. In any case, scenario <2> can be seen as an example for the question phase.

There is an optimization goal to make process 500 (and system 100) more tolerant to changes in the material. In other words, the process should enter one of the alternative phases (cf. FIG. 2).

Optimized scenario <3> stands for an alternative phase (i.e., tolerance enhanced process), for material with the enlarged min-max-range (as in scenario <2>) but with at least one operation parameter that was modified. In the example, parameter P3 was modified to parameter P3′. The process would no longer be in the (quasi) standard phase or in a question phase, but would nevertheless result in the pre-defined product (QY=1, product complies with the specification). Scenario <3> corresponds to an alternative phase.

In that sense, operation parameter P3 can be considered to be a make-or-break parameter: in a suitable setting, the parameter P3′ (after modification) makes process 500 tolerant to material changes (within certain ranges) so that process 500 can transit to an alternative phase.

The figure is simplified. In real-world systems, modifying a single parameter may not change the process as ideally as illustrated. Product Y may remain a pre-defined product, but other properties of the process may change as well. But the benefit of having the process tolerant (as in <3> alternative phase) may overcome disadvantages such as for example, increased energy consumption, or longer phase duration.

By and large, standard material and original operation parameters (in scenario <1>) lead to pre-defined products, but there is a goal to let the system use material in different mixtures. Modifying operation parameters is a way to achieve this goal.

Other optimization goals may comprise the increase in tolerance to other conditions, such as to make the quality (such as QY) less dependent on operation parameters that may change over time, but to that system operator 190 does not have much influence (such as to varying availability of electrical energy).

### Simulation

The bottleneck in updating process 500 is the identification of the operation parameters that could “make” or “break” the process, i.e., the identification of the candidate parameter. Due to the relatively high number of operation parameters (N as explained), such identification appears like a needle-in-the-haystack search. In other words, there is no single parameter P3 out of few parameters, (as in FIG. 1), but P3 has to be identified from many others.

The description now shortly returns to FIG. 1. System operator 190 can change his or her role to become simulator operator 290. The roles of system operator 190 and of simulator operator 290 can be allocated to the same person, or to different persons. Interaction between the roles is possible and desired. Simulator computer 200 simulates process 500 (running on system 100), and identifies one or more operation parameter P_cand as modification candidate. Simulator computer 200 presents the candidate parameter P_cand (or its representation p_cand) to simulator operator 290 via a user interface (UI), not illustrated here. The approach can be understood as an indication of the status of system 100 as a technical system. System operator 190 can then decide to actually modify the parameter (as P_cand becomes P3′ in FIG. 4) or not.

FIG. 5 illustrates a flow-chart diagram of computer-implemented method 600 to identify the operation parameter of an industrial process (500) as a candidate for modification P_cand. Simulation computer 200 performs simulation in instances 601-j (j=1 to J), performs classification 602 (for instances j=1 to J in step evaluating 640), and performs evaluation 603 (with steps 650, 660, 670).

As illustrated by step 680, simulator computer 200 may repeat some of the steps. A virtual line on the figure—with two arrows—goes from step 680 to the simulation in steps 610/620/630. The repetition is conveniently performed with a lower number of instances J′ (smaller than J).

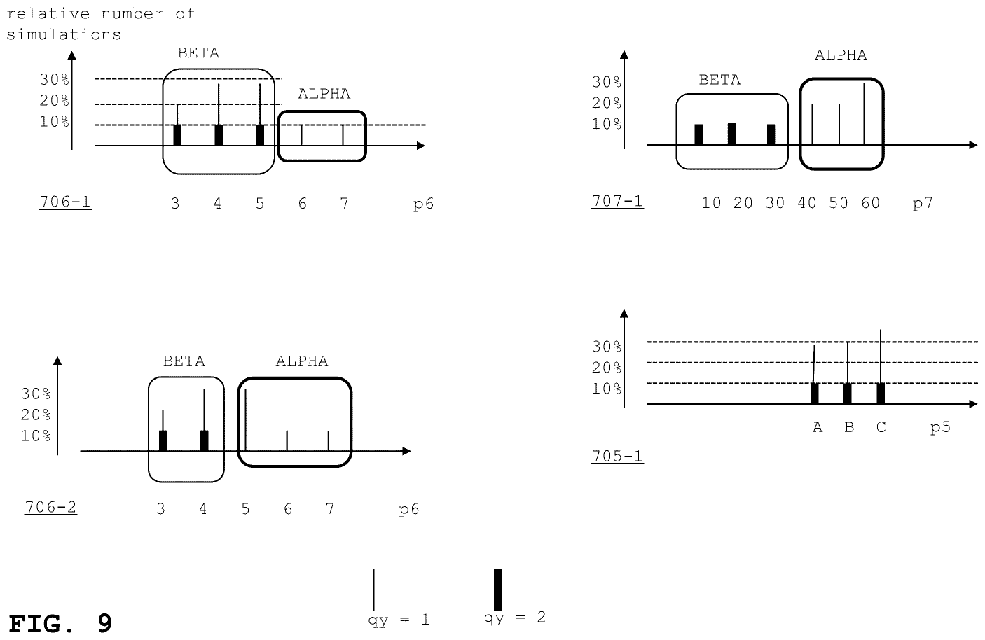

FIG. 5 further illustrates a step 690 by that the computer identifies the candidate for modification (for example P3′ or p6, p7 in FIG. 9) to operator 190 (via a user interface or the like). More in detail, the computer identifies the candidate as the at least one parameter that for the simulation represents an alternative process phase of the industrial system 100 that takes in material X as an alternative mixture of substances X1, X2, X3, performs activities of the pre-defined industrial process 500 according to an alternative operation parameter set (P′), and delivers the pre-defined product Y.

Step 690 follows a loop step by that the simulation is repeated. For simplicity, the cut-condition (to stop simulation, to stop the repetition) is not illustrated. Simulation can be stopped under conditions such as the following:
(1) There is only one parameter candidate that would comply with the condition. (2) There is no candidate identified (repetitions in variations would only lead to qy=2, i.e., question or off-range phases in the notation of FIGS. 2-3). (3) All variations would lead to qy=1 (as the quality is predefined, there is improvement possible, unless the quality indicator QY would to be redefined). (4) Other conditions can be applied as well, for example taking phases into account (with an example to be explained at the end of this description).

Simulator computer 200 comprises simulator module 350 that performs the simulation in multiple simulation instances 601 (cf. for example, by repeating instances), material tuple variator module 340 that enables simulations for different material by providing material variants, operation parameter variator 360 that enables simulations for different operation parameters by providing parameter variants, instances classifier module 390 that classifies the instances into classes (corresponding to phases, cf. FIG. 3), evaluator 370 that tracks the variants and the classes, and that identifies the candidate parameter (and that performs some other tasks such as clustering and interacting with simulator operator 290).

Variator modules 340 and 360 can collectively be referred to as tuple variator module 340/360.

Simulator module 350 that has model 300 as data input. The skilled person can implement the simulation otherwise, but the model-on-module notation is convenient for illustration. Simulator computer 200 uses model 300 as the representation of industrial system 100 and industrial process 500. For convenience, the figure illustrates model 300 by graphical symbols that are similar to the symbols for system 100. Model 300 uses numerical values instead of parameters. In simulator computer 200, material tuple x=(x1, x2, x3) represents material X, and the tuple elements x1, x2, x3 represents substances X1, X2, X3 of material X (cf. step receiving 610). Operation parameter tuple p=(p1, p2, p3, . . . , pN) represents the parameter set P, and tuple elements p1, p2, p3, . . . , pN represent the operation parameters P1, P2, P3, . . . , PN of system 100 individually (cf. step receiving 620). Product tuple y=(y1, y2) represents the product Y, and the tuple elements represent the individual properties of the product Y (cf. step providing 630).

The tuple notation can have the short form with single letters as in “x”, “p” or “y”, and can have the long form, such as in x=(x1, x2, x3), p=(p1, p2, p3, . . . , pN), or y=(y1, y2). The number of individual elements in each tuple can be different. Having 3-tuples, N-tuples and 2-tuples is just an example.

Tuple elements can be numeric values, such as scalars (for percentages), or vectors, and the numeric values of the elements represents the attribute. For example, a parameter Pn may change over time and the computer would represent such as changing parameter by tuple elements pn that could be a vector (e.g., to indicate the temperature as an attribute that changes over time). The parameter tuple p would then be considered a matrix.

As explained above for system 100, parameters (material parameters, operation parameters) have the parameter attributes in attribute ranges. This concept from system 100 is taken over to simulator computer 200 as well. Therefore, the tuple elements (that represent individual parameters) have attributes, with attribute ranges.

To take the above-mentioned temperature parameter as an example, the attribute can be the particular attribute 1.000° C., in the ranges between 1.000° C. and 2.000° C., and the value spacing can be 10° C.

The skilled person can apply the appropriate coding: numeric values for numeric attributes, binary values for binary attributes (for example, a valve being CLOSED or OPEN).

However, there are some particulars in simulation: Simulator computer 200 processes contiguous parameters by digital attributes (after analog to digital conversion). Simulator computer 200 does not have to apply the value spacing (of system 100, and not that of the system computers), but can apply different spacing (e.g., 100° C. in the computer, instead of 10° C. in the system). Making the spacing larger (e.g., from 10 to 100) may save computation resource when simulator computer 200 performs multiple simulation instances (cf. the variations {x}, {p}).

Simulator module 350 has at least one output. In the simplified illustration the output is the product tuple y (that represents the product Y at the output of system 100).

Computer systems with simulator modules and models are known in the art, and commercially available. For example, Aspen offers process simulation software (Aspen Technology Inc. Bedford, MA 01730, United States). It can be assumed that simulator module 350 (with model 300) operates sufficiently accurate so that, for example, the product tuple y corresponds to product Y (within pre-defined tolerances).

It is convenient that simulator computer 200 can use its UI to graphically present model 300 to simulator operator 290. The UI can also present p_cand and—optionally—present intermediate results, such as histograms (cf. FIG. 9).

The skilled person can calibrate simulator module 350 to system 100, accordingly. The skilled person can apply criteria, such as the correspondence of parameters in the real system to the representations in simulator computer 200, the correspondence between product Y and product tuple y, and other criteria.

A simulation instance has an analogy to the above-mentioned process phase. It is therefore possible to apply the class criteria of the phases (cf. FIG. 3) accordingly. Simulation instances result in product tuples y=(y1, y2), but not in products as the process phases do. The quality check comes next, cf. step 640 in FIG. 5.

As illustrated, simulator computer 200 has instance classifier module 390 that (at least) receives product tuple y and that classifies (step 640) the instances into first class instances and second class instances. The classes can be regarded as quality classes.

The description herein explains the classification with the main criterium. Instance classifier module 390 comprises functionality to check product value tuple y=(y1, y2) against the pre-defined specification (for the pre-defined product).

In other words, simulator computer 200 uses instance classifier module 390 to differentiate (step 640) simulation instances (j) into first class instances (that result in product tuples y that would represent products Y as pre-defined products), and second class instances otherwise (Y would be off-products). QY=1 in the process phase corresponds to qy=1 (first class simulation instance), and QY=2 in the process phase corresponds to qy=2 (second class simulation instance).

Instance classifier module 390 can differentiate the simulation instances into first and second class instances by applying further criteria, such process related criteria (cf. FIG. 3, auxiliary criteria).

FIG. 1 illustrates instance classifier module 390 as a module that is independent from simulator module 350 (the specification is provided by system operator 190 and/or simulator operator 290, but usually not by the manufacturer of simulator module 350).

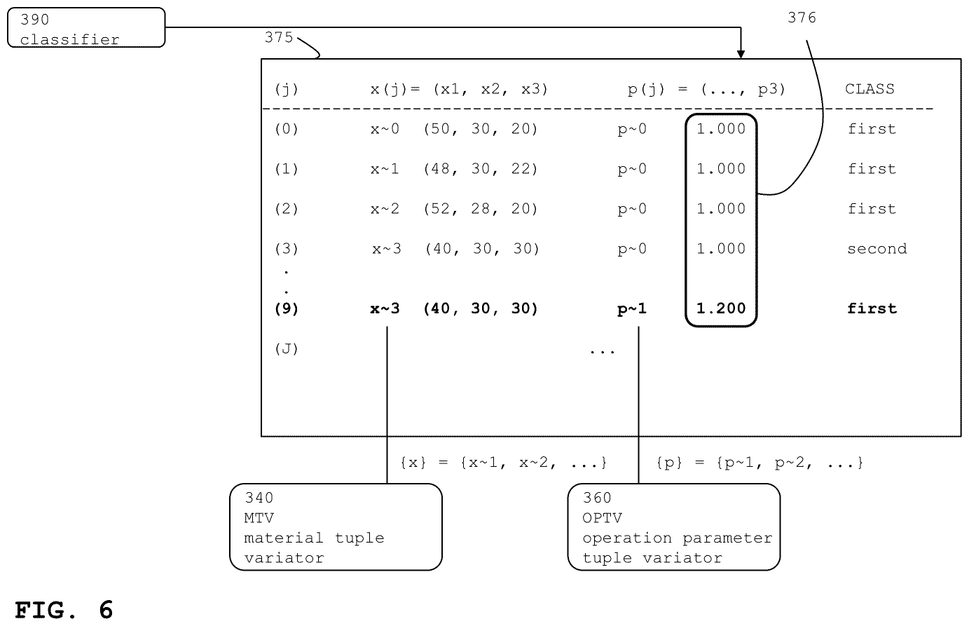

To give an example (cf. FIG. 6), simulation instances with material tuples x=(50, 30, 20), (48, 30, 22), or (52, 28, 20) lead to quality indicator value qy=1 (first class instances). The simulation instance with x=(40, 30, 30) leads to quality indicator value qy=2 (second class instance).

Having explained the output of the simulation (i.e., the classification into first and second classes), the description now investigates activities (at the input) of simulator module 350 (before simulator 350 performs a single simulation).

Material tuple variator module 340 (MTVM) varies the material tuple x=(x1, x2, x3), and parameter tuple variator module 360 (PTVM) varies the operation parameter tuple. This is also illustrated in FIG. 1 by step 610 (simulator module 350 receive x in variants {x}), and step 620 (receives p in variants {p}). MTVM 340 has its analogy in a material supplier for system 100, and PTVM 360 has its analogy in system operator 190 who modifies operation parameters.

FIG. 6 illustrates a tracking list 375 by that evaluator 370 keeps track of simulation instances (j) with parameter tuples in variants and with the classes (first, second) Some simulation instances will show quality indicator values at qy=2 (instance of second class), some others at qy=1 (first class). By way of example, reference 376 indicates the attributes of the parameter element p3 (representing temperature), there are two different attributes (1.000° C. and 1.200° C.). The skilled person can handle the simulation results otherwise, and using a list or a table is just an example that is convenient for explanation.

It is again noted that simulator module 350 processes substantially all parameters elements p1, p2, p3, and so on. It is convenient, that operation parameter tuple variator 360 varies tuple elements that represent parameter for that the attributes can vary in real systems (see below, keeping CARD{y} well below Π).

In the standard scenario, cf. <1> in FIG. 4, system 100 performs process 500 with relatively narrow tolerance in view of material X and of the parameter set P. Potentially, the operation parameters had been selected to have the yield (of Y) as high as possible.

As mentioned, system operator 190 may be confronted with material X that is available but that is out of standard. Simulator computer 200 can assist simulator operator 290 by simulating the process with other materials (and parameters) and instance classifier module 390 could indicate if the available material would be suitable for a process phase (cf. FIG. 2 to run an alternative phase).

Material tuple variator module 340 varies the material tuples for different instances (j). The example of FIG. 6 illustrates material tuple x=(x1, x2, x3) in material variants x˜0, x˜1, x˜2 and x˜3. Variants x˜0, x˜1, x˜2 correspond to the (quasi) standard.

Operation parameter tuple variator 360 also varies the operation parameter tuple p(j)=(p1, p2, p3) for different instances. For simplicity, the figure only illustrates a variation in element p3 (e.g., representing a temperature).

For example, simulation operator 290 sees that simulation instances variants x˜0=(40, 30, 30) and p˜0=(p3=1.000° C.) lead to first class instances, but that x˜3=(40, 30, 20) p˜0=(p3=1.000° C.) lead to a second class instance.

However, there is a possibility to identify the option to successfully run the process with material X(9)=(49, 30, 30) as well but with a modified temperature (parameter P3′=1.200° C. instead of original P3=1.000° C.). This is illustrated for the class instances simulated for variant x˜3 in combination with variant p˜1.

### Theory

Different tuples are variants if at least one tuple element is different. In a first example, variant x˜1=(48, 30, 22) is different to variant x˜2=(52, 28, 20) because the elements are different (here all elements are different in their attributes). The example of FIG. 6 assumes a spacing of 2 mass percent points for the material (e.g., from x2=30 to x2=28). Assuming the above-introduced range between X=(10 . . . 70, 20 . . . 50, 10 . . . 30) and a spacing 2, there are (2=31*16*11 theoretically possible variants from x˜1 to x˜5456. Ω can be the theoretical cardinality of {x}.

In a second example, variant p˜0 is different to variant p˜1 because parameter element p3 has the different attributes 1.000° C. and 1.200° C. Again, for a spacing of 100° C. there can be 11 different attributes for p3. But there is no single attribute p3 to vary but many more: {p}={p˜1, p˜2, . . . , p˜Π}. Π can be the theoretical cardinality of {p}.

However, simulating the process in (2*Π instances would consume electrical energy (by simulator computer 200) in non-desired amounts, and with material X arriving at system 100, there would be simply no time to identify (and actually change) the parameter set.

In the following, the description explains ways to limit the number of simulation instances (cf. FIG. 5), by receiving x with CARD{x}<22 and receiving y with CARD {x}<Π. Limitations in intermediate steps (after classification 602/640 before repeating 601) are also applicable. For example, clustering can be performed for a subset of parameter values (N #<N), determining significance (step 660) further limits the number of simulations.

FIG. 7 illustrates a status-diagram to show simulation and other activities by computer 200. The figure can be understood to explain a simulation strategy.

FIG. 7 illustrates simulation instances by “round-shaped” rectangles that are arranged on the drawing similar as the phases in FIG. 2. Multiple instances are indicated by overlaying rectangles. Depending on the product Y that the simulator outputs as product tuples y, simulation instances are either first class instances or second class instances (as already explained).

The arrows in the center of the drawing symbolize multiple simulations (for example by repeating simulations), with multiple instances across different material (to the left), and multiple instances across different parameters (to the right).

Starting from the center that could be considered the standard (no need to simulate, but simulation performed optionally), the computer can modify the representations of the material ({x}, the arrow to the left) and could arrive at quasi-standard instances (expected for relatively minor variations in the material, qy=1, first class), and could arrive at question instances (for relatively large variations in the material, qy=2, second class).

Starting from the center, the computer can modify the representations of the parameters ({y}, go right) and would arrive at alternative instances (first class), or at question instances (second class).

The special case of the computer simulating standard material at the intake and identifying parameters that would also allow to obtain pre-defined product is noted. For system operator 190, identifying some parameter changes are potentially of limited importance, because the new parameter set does not respond to changes in the material availability.

Simulator computer 200 performs multiple simulation instances by varying material tuples and parameter tuples (in variant sets {x} and {p} in relatively coarse granularity (e.g., relatively large attribute differences (“spacing”) between the variants over a relatively large band 10, 20, 30 to 100, relatively narrow band 11, 12, 13, to 20, or otherwise). This approach is in line with the goal to stay much below Ω and below Π.

The computer then evaluates the instances (cf. 602 in FIG. 5), clusters the instances (after simulation, module 390, step 640), determines parameters for that the differences between first and second class simulations are significant (step 660), receives potential relation information to determine parameter values that represent parameters that are technically related (step 670, for example, from simulation operator 290), and—optionally—repeats the simulation with adapted variants (cf. step 680).

The computer applies clustering and identifies parameters (to simulate again) as the result of the clustering. The computer clusters the simulation instances (cf. the first and second instance classes) and identifies at least one parameter. Identifying such a parameter—the candidate parameter—allows system operator 190 to identify a further alternative phase (given in bold) that would be suitable for alterative material (cf. FIG. 2).

System operator 190 can then decide to modify the parameter so that the process can run again.

Regarding the simulation, there is potential to save computation resources, for example, as it will be explained for FIG. 9, clustering is not applied for all N parameter value, but for N #<N, and the repetition can be performed for a smaller number of instances J′<J.

The efficiency of simulating (and evaluating with clustering) can be enhanced by differentiating parameters, the potential advantages of differentiating parameters will become more visible in view of the simulation that the description explains next.

### Restricting the Number of Material Variants

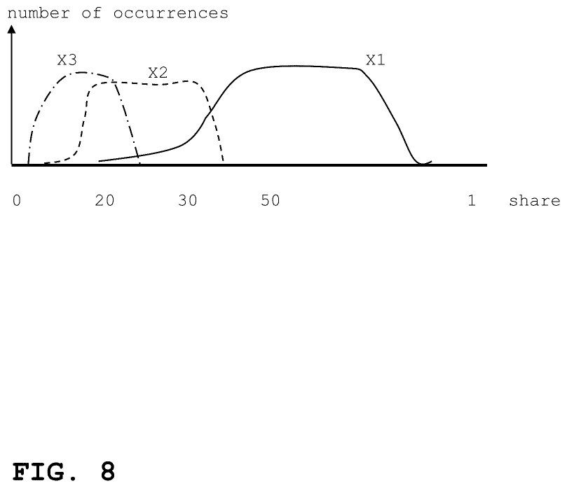

FIG. 8 illustrates a simplified histogram of historical material mixtures X. The computer can generate variants based on that. The example shows histograms for substances X1, X2 and X3. By processing historical data-such as historical observations of the real-world—tuple variator module 340 can identify value ranges for the shares of the substances. In other words, module 340 can determine shares of the substances in value ranges with boundaries (such as upper and lower boundaries). The boundaries (real-world observations) correspond to boundaries of the elements in the material tuples, and the variator module varies the elements within these boundary elements.

For example, the share of substance A has been determined to vary between 30 and 80 percent, the share of substance B has been determined to vary between 18 and 32 percent, the share of substance C has been determined to vary between 4 and 24 percent.

The lower boundaries are 30 for X1, 18 for X2, and 4 for X3; the upper boundaries are 80 for X1, 32 for X2, and 24 for X3.

As the shares may not be distributed equally, module 340 can identify the boundaries by accessing likelihood data. In a first example, a particular share is within its boundaries for a likelihood of occurrence above a particular threshold: X1=30 may occur and thereby exceeds a particular threshold (e.g., occurrence in 5% or more situations), but X1=29 may not. X1=80 may have the occurrence likelihood about the 5% threshold, but X1=81 does not.

In a second example, the mixture (82, 9, 9) might have been seen indeed on rare occasions, but with an occurrence percentage below a threshold (that considers the likelihood for the mixture). Therefore, such a mixture can be ignored for the simulation, so that computation resources can be saved.

It is also possible to determine the boundaries by assuming particular distributions. Taking the normal distribution (Gauss) as an example, the boundaries can be calculated by the median μ and the standard deviation σ. For example, μ (X1)=55 can be share at median, and the boundaries can be calculated to be μ−σ and μ+σ. The skilled person can apply “factor*σ”, or can apply other approaches, among them the application of distributions applied to the mixtures.

Therefore, material tuple variator module 340 will vary the mixture values accordingly (for the simulation). It will not calculate approximately 100×100×100 theoretical variants (with a one percent step, or 1.000.000), but 51×15×21 more practical variants. The cardinality of the material variant set would be approximately 16.000 (or 16 per mille of its theoretical number (2).

The attribute spacing (here of one percent) is just taken as an example, the spacing can be taken differently.

In other words, distribution of substances (X1, X2, X3) are more likely to occur than others, and material tuple variator module 340 can take feasible distributions into account.

Restricting the number of material variants (for simulation) can reduce the number of simulations to perform (cf. the number of simulation instances J), so that the computer performing method 600 would need less time and less resources.

### Restricting the Number of Operation Parameter Variants

The principle of taking value ranges into account can be applied accordingly. For example, operation parameters can have value ranges (with lower and upper boundaries). A temperature in a value range between 0° C. and 2.000° C. could be input to a simulation with a granularity of approximately 2.000 different temperatures (one degree step), but the simulations would use variants in coarse granularity, such as for 100° C. (i.e., larger spacing).

### Clustering Instances to Identify Parameter Candidates

Assuming that computer 200 (with simulator module 350) has performed multiple simulations (J) and that instance classifier module 390 differentiated the instances into first and second class instances (cf. step 640 in FIG. 9). Although the first class instances indicate alternative parameter sets, they do not yet indicate the candidate parameter P_cand. In other words, pre-liminary results (following classification 640) do not yet tell system operator 190 what to do. A particular first class instance would show potentially many parameters that would be different from the original parameter set (i.e., from the parameters of the standard phase). The operator would not change many parameters. There is a preference to change at least one parameter (the candidate). Clustering is one step in finding this. The description refers to FIG. 6 for the example of one parameter value and to FIG. 9 for the example with multiple parameters values.

As in FIG. 6, operation parameter value p3 has the two attributes 1.000° C. and 1.200° C., and qy (j) leads to first class and second class instances.

Tracking list 375 comprises the identification of the variants, such as x˜1, x˜2, x˜3, y˜0, y˜1 and so on. Much simplified, at this stage of the overall process, the variants do not matter, and the individual mathematical values of the material elements (x1, x2, x3) and/or the attributes of the operation parameter elements (p1, p2, p3) have to be looked at.

For a subset of parameters (N #<N), the instances are clustered, in two-dimensions, according to the quality classes (first and second class), and according to the attributes of that operation parameter (e.g., the temperature 1.000° C., 1.200° C.).

In the much simplified example of FIG. 6, clustering is illustrated for parameter value p3 only. Two-dimensional clusters can be made with instances (0), (1), (2) in cluster 1.000/1, instance (3) in cluster 1.000/2, and instance (9) in cluster 1.200/1.

Clustering is applicable, no matter if the parameters are direct parameters (as in FIG. 6, target temperature), or indirect parameters (as in FIG. 5).

FIG. 9 illustrates the clustering of simulation instances for selected parameters, with clustering according to attribute values (first dimension) and to instance classes (second dimension, first/second classes).

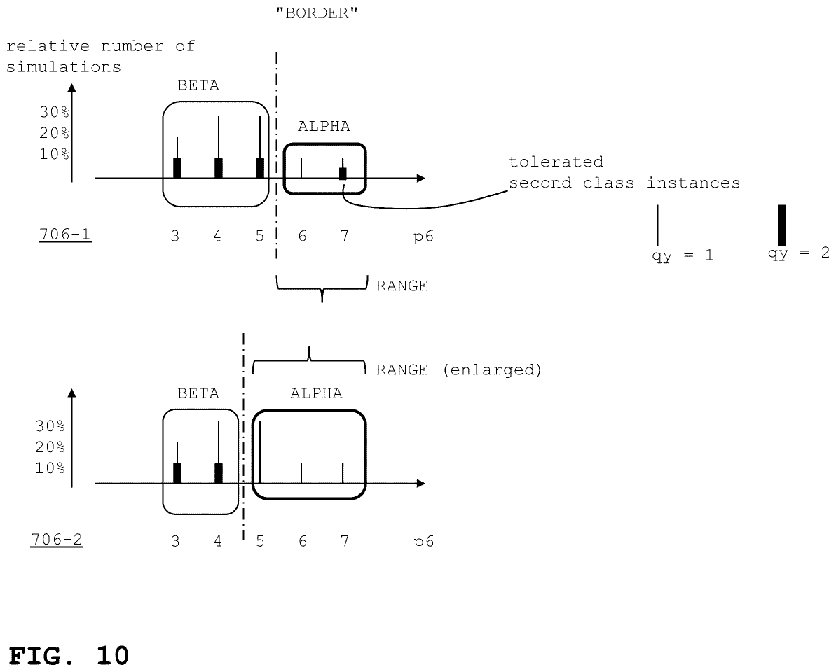

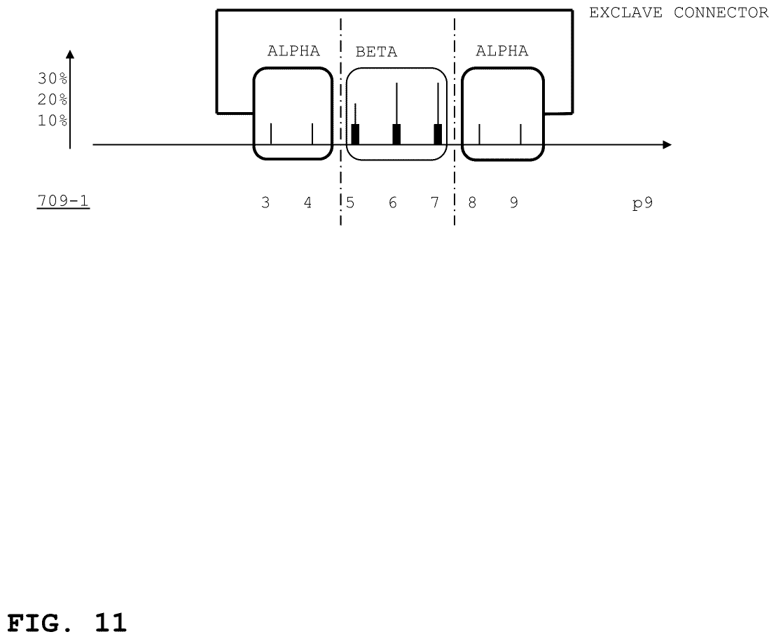

FIGS. 10 and 11 repeat the illustration of FIG. 9, at least in some parts but add further details.

For simplicity, the computer has performed multiple simulations for p=(p1, p2, p3, p5, p6, p7, p8, p9, p10) for that N #=3 parameter elements p5, p6, and p7 have been varied (cf. {y}). The material variant was the same for all repetitions (i.e., CARD {x}=1).

Histograms 705-1, 706-1 and 707-1 show simulation details for parameters p5, p6, and p7, respectively. There is no need to present the histograms or other visualizations to simulator operator 290. The presentations do not even have to be in the form of histograms, clusters do not have to be identified by round-shaped rectangles, and quality classes do not have to be given by lines.

Histogram 706-2 shows the result of further simulation repetitions (cf. step 680 in FIG. 5).

The X-axes show the attributes for each parameter value separately: p5 has attributes values A, B, and C; p6 has attribute values 3, 4, 5, 6, and 7; and p7 has attribute values 10, 20, 30, 40, 50, and 60.

The Y-axes show the number of simulation instances per attribute, normalized to relative values (for example, J serving as the 100% reference) by vertical lines: Regarding p5 (direct parameter), the computer used the attribute A in 30%, B in 30% and C in 40% of the simulations. Regarding p6 (indirect parameter), the attribute 3 occurred in 20% of the simulations, 4 in 30%, 5 in 30%, 6 in 10% and 7 in 10%. Regarding p7 (direct parameter), the computer used the attribute 10 in 10%, 20 in 10%, 30 in 10%, 40 in 20%, 50 in 20%, and 60 in 30%.

As explained, instance classifier module 390 determines quality indicator value qy and thereby also classifies the instances. The histograms show this classification as well. Thin lines indicate that the simulation leads to first class instances (qy=1 as main criterium, cf. FIG. 3), and bold lines indicate that the simulation leads to second class instances (qy=2). The difference between thin and bold lines is also given in a legend.

As explained, evaluator module 370 performs clustering by using predefined rules. The computer clusters the instances by attributes (first dimension) in combination with classification into first or second classes (second dimension).

Clustering leads to the identification of a first cluster (here called ALPHA) and of a second cluster (here called BETA). Clusters do not overlap: a particular simulation instance either belongs to the first cluster or to the second cluster.

Clustering also leads to the identification of a “cluster border” and of a “cluster attribute range” (cf. FIGS. 10 and 11). Both terms are convenient to illustrate clustering, but both represent the same concept: the computer also identifies attributes that separate the clusters. The “cluster border” can be given as the attributes that mark the end of the first cluster and the begin of the second cluster (along the attribute dimension). The “cluster attribute range” can be regarded as the set of attributes for instances in a particular cluster.

Again, visualizing clusters is not required, and terms such as “border” or “range” are understood to be metaphors that are convenient for illustration.

The first cluster is the cluster in that (substantially) all instances are first class instances, and the second cluster is the cluster for the remaining instances.

In the example of FIG. 9, histogram 706-1 shows first cluster ALPHA with the attribute range (6, 7) and second cluster BETA with the attribute range (3, 4, 5), with the “border” between attributes 5 and 6. (Attribute ranges can also be noted otherwise, such as range 3<=attribute <=5).

Histogram 707-1 shows first cluster ALPHA with the attribute range (40, 50, 60) and second cluster BETA with an attribute range (10, 20, 30), with the “border” between attributes 30 and 40.

The description simplifies the discussion by discussing first clusters ALPHA in that ALL instances are first class instances. In the example of histogram 706-1, cluster ALPHA comprises first class instances only (thin lines only), in histogram 707-1 cluster ALPHA comprises first class instances only, as well.

It is however possible to have a rule that tolerates a pre-defined fraction of class instances to be second class instances. For example, histogram 706-1 in FIG. 9 illustrates first cluster ALPHA in that 20% (of all simulations) are first class instances, and illustrates second cluster BETA in that 80% (of all simulation) are either first or second class instances. Histogram 706-1 in FIG. 10 shows a short bold line with a tolerated number (of share) of second class instances in ALPHA. For example, ALPHA could have 18% (of all simulations) as first class instances, but could also have 2% (of all simulations) as second class simulation. In other words, 90% of the instances in ALPHA are first class instances, and 10% of the instances in ALPHA are second class instances, with the tolerance inside the cluster at 10%. The tolerances could be applied and defined otherwise.

Attribute ranges do not have to be contiguous. FIG. 11 shows an example for parameter value p9 with ALPHA in the range (2, 3, 8, 9) and BETA in the range (5, 6, 7). There would be two borders. The situation could be reversed, with ALPHA with a contiguous range in the center (of the X-axis) and with BETA in two parts at the edges. In other visualizations, ALPHA may be illustrated as having “exclaves”. In FIG. 11, the two parts of ALPHA are illustrated by a line labelled “exclave connector”.

Regarding the computation, it does not matter if evaluator module 370 starts by the attributes or by the class, the differentiation of first and second dimensions is just convenient for explanation.

The skilled person is familiar with the concept of clusters, so that the description stays with examples and describes exemplary rules in words.

As for histogram 706-1, the computer applied a rule to find “all first class” instances. Cluster ALPHA comprises the instances for attributes 6 and 7, leading to first class instances. Cluster BETA comprises the remaining instances, i.e., instances with attributes 3, 4, and 5, with both first class instances (qy=1) and second class instances (qy=2).

As for histogram 707-1, the computer applied a rule to find instances in that the class remains the same for separate attribute value ranges: Cluster ALPHA comprises the instances for attributes 40, 50, 60 (i.e., a range as well) all being first class instances. Cluster BETA comprises the instances for attributes 10, 20, 30 (i.e., the attribute range) all being second class instances. As for histogram 705-1, the computer applied the range rule but did not find a cluster (at least not for that rule). Not identifying a cluster is a useful information for the computer: the attribute (here: A, B or C) does not matter, in all cases there would be uncertainty in the products (qy=1 and qy=2).

As used herein, if the (successful) application of a rule separates instances into at least two clusters, so that all instances are allocated to a particular cluster (e.g., ALPHA, or BETA, but not to both).

The skilled person can-optionally-apply statistical metrics to determine if one of the two clusters has a significant influence on qy, and therefore the parameters would be candidate to be modified. Taking percentages as symbols for such metrics is just illustrative. For ALPHA in 706-1 comprises 20% of the instances. The skilled person can use other (more sophisticated) metrics, such as cross-referencing, the t-test, support vector machine (SVM), or the k-nearest neighbors algorithm.

In the example, the clusters for parameter value p6 (in histogram 706-1) and p7 (in histogram p7) are significantly different (within their histograms). Such difference can indicate at least two consequences: First, p6 in value 6 or 7 can be a candidate (the operator could apply it as P6 in the corresponding values). Second, the computer can start further simulations with reduced load to its computing resources, in view of interrelation between this parameter P6 and other parameters, by optimizing the use of above-mentioned cause-effect relations.

In other words, the computer can apply an estimation if further (more accurate) simulations would be justified (in terms of using computer resources): modifying p5 (as in 705-1) would likely not lead to cluster enhancement (or finding a cluster at all), but modifying p6 would be more justified.

In situations where two parameters are technically related, modifying a (direct) parameter may change a further (direct, or indirect) parameter and may allow the technical system to run in a (further) alternative phase.

The simulation instance does not consider such relations, but clustering (and subsequent determining significance or not) identifies two or more parameters (parameter values in the simulation).

The computer now determines if parameters (for that the simulations lead to clusters, optionally to significantly different clusters) are technically related. This step is optional for situations in that a range enhancement (the attribute range get larger, cf. 706-1 and 706-2) is anticipated (by repeated simulation).

By way of example, the description assumes that the computer optionally presents histograms with identified clusters (such as ALPHA, BETA) to simulator operator 290, so that the operator can relate two (or more) parameters.

In the example, the computer should have presented the clusters for p6, p7, and p9 (not illustrated here in the figures) to simulator operator 290, and that simulator operator 290 has related p6 and p7 (as standing for parameters that are related in system 100). In other words, the computer has interacted with simulator operator 290 with the result to have two parameters P6 and P7 (and the values p6, p7) that are technically related.

In this fictitious example, P6 and P7 may belong to a heat exchanger, with P6 standing for a temperature difference, and P7 for a physical property of the heat exchanger (such as mass flow).

The computer repeats the simulations, by modifying attributes of p6 and p7 (i.e., of the related parameters), and clusters again, cf. histogram 706-2 for parameter P6 (p6 as simulated). Compared to earlier simulations, p6 has a first class cluster with an enlarged attribute range (compared to 706-1, from (6,7) to (5, 6, 7)). Parameter P6 is therefore confirmed to be a candidate for modification (to be in the attribute range between 5 and 6, or even to 7). Although P6 can not be changed directly (because it is an indirect parameter), there are ways to modify it nevertheless (indirect via parameter P7).

Simulator computer 200 can present histogram 706 to simulation operator 290. Simulation operator 290 understands that simulations with p6=6 and p6=7 frequently occur for simulations instances with qy=1.

This does not mean that parameter P6 (represented by element p6) would lead to QY=1 (if in the range 5, 6 or 7) but this is an indicator that parameter P6 is a modification candidate.

Or, from the perspective of alternative phases, attributes P6=6 and P6=7 belong to alternative parameter sets, that would lead to products being pre-defined.

In theory, the computer can provide clusters according to parameter attributes (first dimension) and according to quality indicator values (second dimension).

### Further Repetitions

The bold printed instances (for the second class) should disappear so that the attribute range for qy=1 is enlarged from 6-7 to 5-7. In other words, there is a desire to collect more members (i.e., instances) for the “alternative” cluster (i.e., an alternative first cluster, or ALPHA cluster).

The computer could continue with further simulation (simulations in that p6 has the attributes 6 or 7). In the further simulation, parameter values should be varied that potentially change p6 (cf. the repetitions in step 680).

Given the situation that the number N (of operation parameters) is relatively high, the computer could in theory provide N of such first dimensions. This would—however—not be suitable to identify modification candidates.

The description therefore discusses the selection of operation parameters with more detail.

### Parameter Differentiation

In theory, operation parameter tuple variator 360 (OPTV, FIG. 1) can vary all parameter values (in model 300) so that simulator module 350 could simulate the process in a relatively high number of simulation instances. As simulator computer 200 consumes resources (such as electrical energy, computation time, etc.) it is desired to keep the number of simulations as low as possible. As explained already, clustering instances and other actions help to reduce the number of parameter variations.

Parameter values can be varied according to the feasibility that the system operator will parameter modifications in the real-world system. In other words, there is a likelihood that a candidate parameter is actually modified in the system. Low feasibility corresponds to low likelihood. The following discussion assists the skilled person program operation parameter tuple variator 360 accordingly.

In principle, limitations are contemplated in at least two aspects: (i) Variator 360 can provide variations in {p} in view of system 100 being a realistic system. For example, the direct parameter of the target temperature has attributes that are realistic for the system (e.g., between 1.000° C. and 2.000° C., but not 20.000° C.). (ii) The computer can provide the instance clusters (by presenting them to the simulator operator 290) for parameters that the operator can actually modify. In other words, non-realistic parameters should be filtered out and should not become candidate parameters. For example, electrical power consumption of a heater unit can not be increased unless the unit is replaced (process re-design), but that would not be realistic.

The description now investigates potential parameter value modifications by differentiating parameters and parameter value according to some further criteria.

Parameters can be differentiated according to the relation of the parameter to system and process: System parameters are related to system 100 (e.g., the dimension of a cooler or heater component). Process parameters are related to process 500 (e.g., the step order to be changed). The parameter set P=(P1, P2, P3, . . . ) can be separated into sub-pluralities, but both sub-pluralities can overlap. A particular parameter can be both a system parameter and a process parameter. For example, the use of a particular chemical reaction (by that two substances react with each other to a further substance) is a process parameter, but the technical details for corresponding unit are system parameters (size, volume, pressure, status of valves etc. of the unit).

Operation parameters can be differentiated according to their relevance to process 500 or to individual sub-steps of process 500. Relevant parameters usually stay within pre-defined attribute ranges (so that the simulation stays within such ranges). For example, a catalyst may operate in a particular temperature range, otherwise it would not act as a catalyst. Relevant parameters can be process parameters or system parameters.

Parameters can be differentiated according to the modality of being changed. System-down parameters can only be changed when system 100 is deactivated, at least partially. For example, a cooler can be replaced by a cooler with a different dimension, but only during maintenance. Or, a heater is electrically powered at 380 V/10 KW and can be replaced by a heater at 20 KW. Before and during the replacement, the system is not running, or is not running in full scope. System-on parameters can be changed when the system is running. By and large, it is more feasible to change a system-on parameter than to change a system-down parameter.

Parameters can be differentiated according to the interaction with human operators (cf. operator 190) when they are to be changed. Some parameters require the interaction of human operators (the operator switches a component on or off). Some parameters do not require the interaction of human operators, they can be controlled by a computer. The change feasibility can be different for both groups. It is possible to perform the simulation with a preference, such as to prefer non-interaction parameters over interaction parameters.

Parameters can be differentiated according to intrinsic properties of substances or equipment. Fixed parameters can not be changed at all. For example, the melting temperature of particular substance can not be changed. Or, a particular order of adding substances to a unit can not be changed. Or, the electrical energy supply can not be changed (a voltage may be 380 V only). Or, a particular substance X can be converted to a particular substance Y, but not vice versa. As a consequence, fixed parameters are to be considered during simulation (by corresponding parameter values), but varying the parameters and subsequently clustering the instances according to such fixed parameters can be avoided.

Direct and indirect parameters have already been discussed above. For example, a heater can be switched on or off at substantially any time, and the on/off parameters is a direct parameters. Direct parameters (or parameter elements) are the main focus for providing the variation set {p}.

Parameters values can be differentiated according to the time of availability of parameter values. Indirect parameters may have an aspect in their real-time availability. Measurement values are available when the industrial system runs the process, but not earlier. For example, a value can be the percentage of a tank being filled. Status data (of the industrial system being a technical system) becomes available when the system is running. On the other hand, some equipment data is available at substantially any time. For example, the rated settings of a heater (308 V, 10 KW or 20 KW) are available. Or, the volume of a tank is available.

Parameters values can be differentiated according to the ability to obtain the parameter value by calculation. A duration (of a process step or the like) can be calculated. For example, the duration it takes to heat up a particular amount of a particular substance to a particular temperature can be calculated from other parameters (heater type, temperature before etc.).

Some parameters can be modified without re-designing the process, for example, to select a different temperature for a catalyst. But using a different chemical substance as catalyst would require the re-design. Again, the modification likelihood is different so that the parameters without redesign have the preference (of being varied for simulation) over re-design parameters.

### Number of Parameters in Simulation Before and After Clustering

Optionally, computer 200 performs method 600 and thereby uses variator module 360/380 as follows:

Before evaluator module 370 performs clustering 650, variator module 360/380 provides a relatively large number of variations in the material tuple (x) and provides a relatively small number of variations in the operation parameter tuple (p). After evaluator module 370 performs clustering 650, variator module 360/380) provides a relatively smaller number of variations in the material tuple (x) and a provides a relatively larger number of variations in the operation parameter tuple.

After clustering, variator module 360/380 provides the relatively smaller number of variations in the operation parameter tuple (p) as variations of the identified at least two parameter values (cf. p6, p7 in step 660) for that the first and second clusters differ with statistical significance.

Optionally, variator module 360/380 provides the relatively small number of variations in the material tuple (x) as the material tuple that corresponds to the standard material (X) in the standard mixture of substances.

Having a different balance in the number of variants (before and after clustering) optimizes the number of simulation instances, with an optimization goal to avoid an un-necessary simulation instance.

### Discussion

The approach to identify relevant parameters has been illustrated for system 100 and process 500 that are productive (historical data is available). It is also possible to use the approach to design new systems and new processes.

The description has referred to variations of material and the operation parameters by way of example. Variants of operation parameters can comprise variations in energy values. An alternative (or additional) optimization goal could be established to let the system perform the process with less energy.

Simulation results can be taken over to the system, or will be taken over to the system. The skilled person can turn over modified parameter values (from the simulation) into parameters (of the system/process). A parameter being a modification candidate is not yet a modified parameter.

As explained above, every phase of process 500 can be different in the parameters (such as in the material X and/or in the parameter set P). Therefore, every change in a parameter (e.g, in X or in Y or in both) can be considered as the start time for a new phase. New phases lead to new products (i.e., different Y) in product phase. For every new phase, product quality can be classified as QY (qy if simulated). It is possible to define quality in terms of time intervals that are longer than phases (multiple phases per interval). For consecutive quality indicators QY (or qy) such a time interval could be obtain as, for example, a time-series (1, 2, 1, 2, 1, 1, 1, 1, 1, 1). In the example there are 10 phases within the time interval, with 2 phases of 10 phases in QY=2 (or qy=2 if simulated). This perceptual indicator (e.g., 20%) “out of quality” or “off” measure can be used as a criteria, for example to stop simulation (in step 480).

In a further example, the time-interval could be set to last 10 days and changes in X or Y could occur every hour. This would lead to 240 consecutive phases.

### Generic Computer

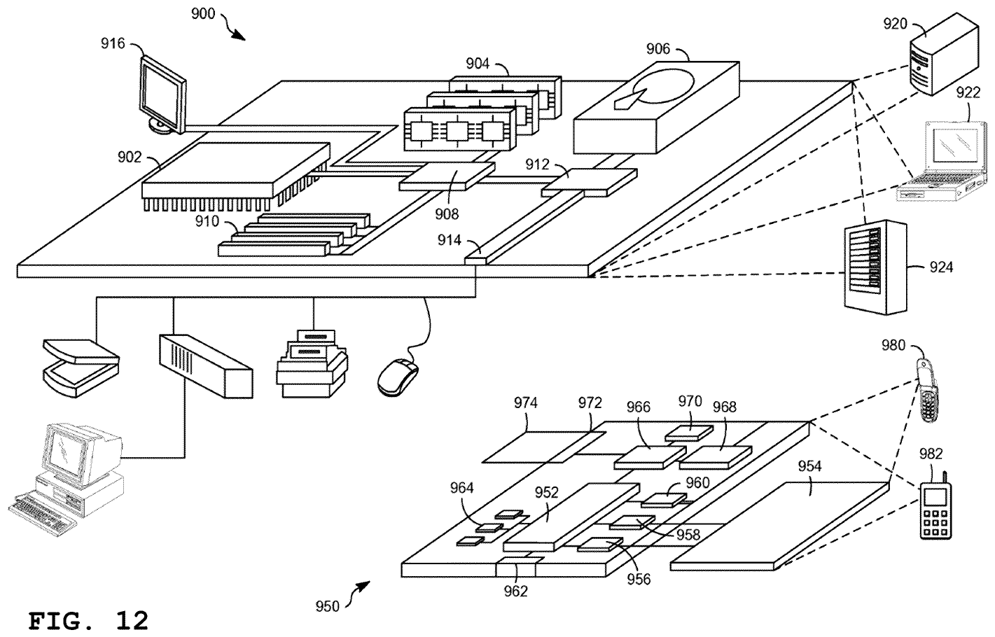

FIG. 12 illustrates an example of a generic computer device 900 and a generic mobile computer device 950, which may be used with the techniques described here. Computing device 900 is intended to represent various forms of digital computers, such as laptops, desktops, workstations, personal digital assistants, servers, blade servers, mainframes, and other appropriate computers. Generic computer device may implement the computing function. Computing device 950 is intended to represent various forms of mobile devices, such as personal digital assistants, cellular telephones, smart phones, and other similar computing devices. The components shown here, their connections and relationships, and their functions, are meant to be exemplary only, and are not meant to limit implementations described and/or claimed in this document.

Computing device 900 includes a processor 902, memory 904, a storage device 906, a high-speed interface 908 connecting to memory 904 and high-speed expansion ports 910, and a low speed interface 912 connecting to low speed bus 914 and storage device 906. Each of the components 902, 904, 906, 908, 910, and 912, are interconnected using various busses, and may be mounted on a common motherboard or in other manners as appropriate. The processor 902 can process instructions for execution within the computing device 900, including instructions stored in the memory 904 or on the storage device 906 to display graphical information for a GUI on an external input/output device, such as display 916 coupled to high speed interface 908. In other implementations, multiple processors and/or multiple buses may be used, as appropriate, along with multiple memories and types of memory. Also, multiple computing devices 900 may be connected, with each device providing portions of the necessary operations (e.g., as a server bank, a group of blade servers, or a multi-processor system).

The memory 904 stores information within the computing device 900. In one implementation, the memory 904 is a volatile memory unit or units. In another implementation, the memory 904 is a non-volatile memory unit or units. The memory 904 may also be another form of computer-readable medium, such as a magnetic or optical disk.

The storage device 906 is capable of providing mass storage for the computing device 900. In one implementation, the storage device 906 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 904, the storage device 906, or memory on processor 902.

The high speed controller 908 manages bandwidth-intensive operations for the computing device 900, while the low speed controller 912 manages lower bandwidth-intensive operations. Such allocation of functions is exemplary only. In one implementation, the high-speed controller 908 is coupled to memory 904, display 916 (e.g., through a graphics processor or accelerator), and to high-speed expansion ports 910, which may accept various expansion cards (not shown). In the implementation, low-speed controller 912 is coupled to storage device 906 and low-speed expansion port 914. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 900 may be implemented in a number of different forms, as shown in the figure. For example, it may be implemented as a standard server 920, or multiple times in a group of such servers. It may also be implemented as part of a rack server system 924. In addition, it may be implemented in a personal computer such as a laptop computer 922. Alternatively, components from computing device 900 may be combined with other components in a mobile device (not shown), such as device 950. Each of such devices may contain one or more of computing device 900, 950, and an entire system may be made up of multiple computing devices 900, 950 communicating with each other.

Computing device 950 includes a processor 952, memory 964, an input/output device such as a display 954, a communication interface 966, and a transceiver 968, among other components. The device 950 may also be provided with a storage device, such as a microdrive or other device, to provide additional storage. Each of the components 950, 952, 964, 954, 966, and 968, are interconnected using various buses, and several of the components may be mounted on a common motherboard or in other manners as appropriate.

The processor 952 can execute instructions within the computing device 950, including instructions stored in the memory 964. The processor may be implemented as a chipset of chips that include separate and multiple analog and digital processors. The processor may provide, for example, for coordination of the other components of the device 950, such as control of user interfaces, applications run by device 950, and wireless communication by device 950.

Processor 952 may communicate with a user through control interface 958 and display interface 956 coupled to a display 954. The display 954 may be, for example, a TFT LCD (Thin-Film-Transistor Liquid Crystal Display) or an OLED (Organic Light Emitting Diode) display, or other appropriate display technology. The display interface 956 may comprise appropriate circuitry for driving the display 954 to present graphical and other information to a user. The control interface 958 may receive commands from a user and convert them for submission to the processor 952. In addition, an external interface 962 may be provide in communication with processor 952, so as to enable near area communication of device 950 with other devices. External interface 962 may provide, for example, for wired communication in some implementations, or for wireless communication in other implementations, and multiple interfaces may also be used.

The memory 964 stores information within the computing device 950. The memory 964 can be implemented as one or more of a computer-readable medium or media, a volatile memory unit or units, or a non-volatile memory unit or units. Expansion memory 984 may also be provided and connected to device 950 through expansion interface 982, which may include, for example, a SIMM (Single In Line Memory Module) card interface. Such expansion memory 984 may provide extra storage space for device 950, or may also store applications or other information for device 950. Specifically, expansion memory 984 may include instructions to carry out or supplement the processes described above, and may include secure information also. Thus, for example, expansion memory 984 may act as a security module for device 950, and may be programmed with instructions that permit secure use of device 950. In addition, secure applications may be provided via the SIMM cards, along with additional information, such as placing the identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 964, expansion memory 984, or memory on processor 952, that may be received, for example, over transceiver 968 or external interface 962.

Device 950 may communicate wirelessly through communication interface 966, which may include digital signal processing circuitry where necessary. Communication interface 966 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 968. In addition, short-range communication may occur, such as using a Bluetooth, WiFi, or other such transceiver (not shown). In addition, GPS (Global Positioning System) receiver module 980 may provide additional navigation- and location-related wireless data to device 950, which may be used as appropriate by applications running on device 950.

Device 950 may also communicate audibly using audio codec 960, which may receive spoken information from a user and convert it to usable digital information. Audio codec 960 may likewise generate audible sound for a user, such as through a speaker, e.g., in a handset of device 950. Such sound may include sound from voice telephone calls, may include recorded sound (e.g., voice messages, music files, etc.) and may also include sound generated by applications operating on device 950.

The computing device 950 may be implemented in a number of different forms, as shown in the figure. For example, it may be implemented as a cellular telephone 980. It may also be implemented as part of a smart phone 982, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing device that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing device can include clients and servers. A client and server are generally remote from each other and typically interact through a communication network. The relationship of client and server arises by virtue of computer programs running on the respective computers and having a client-server relationship to each other.

A number of embodiments have been described. Nevertheless, it will be understood that various modifications may be made without departing from the spirit and scope of the description.

In addition, the logic flows depicted in the figures do not require the particular order shown, or sequential order, to achieve desirable results. In addition, other steps may be provided, or steps may be eliminated, from the described flows, and other components may be added to, or removed from, the described systems.

### REFERENCES

100 industrial system
101, 111, . . . connectors
110, 120, 130 units
190 system operator
200 simulator computer
290 simulator operator
300 model
340 material tuple variator module (MTVM)
350 simulator module
360 parameter tuple variator (PTVM)
370 evaluator module
375 tracking list
376 attribute
390 instance classifier module
500 industrial process
600, 60x, 6xx method, steps
70x histograms
N, N #, n number of operation parameters, index
Pn operation parameter, index n
p operation parameter tuple (indices 1 to n)
P1, P2 intermediate product
P_cand, P3′ example for candidate parameter, modified parameter (p_cand, p3′ during simulation)
QY, qy quality indicator for the product, for the product value
X, x material, material tuple
Y, y product, product tuple
Ω, Π theoretical number of variants
{x}, CARD{x} material variant set, number of variants
{p}, CARD{p} operation parameter variant set, number of variants
I, i process phases
J, j simulation instances
μ, σ median, standard deviation

1. Computer-implemented method to identify an operation parameter of an industrial process as a candidate for a parameter modification, wherein an industrial system, in a standard process phase, takes in standard material as a standard mixture of substances, performs activities of a pre-defined industrial process according to a plurality of operation parameters, referred to as an original operation parameter set hereinafter, and delivers a product, with the product having pre-defined properties, referred to as a pre-defined product hereinafter;
wherein a computer uses a simulator module to simulate the industrial process by accessing a model that represents the system and that represents the industrial process,
wherein the simulator module in each simulation instance receives a material tuple with elements, wherein the material tuple represents the material, and wherein its elements represent substances of the material,
wherein the simulator module in each simulation instance receives an operation parameter tuple with elements, wherein the operation parameter tuple represents the operation parameters set of the industrial process, and wherein its elements represent individual operation parameters as well as their attributes, and
wherein the simulator module in each simulation instance provides a product tuple with elements, wherein the product tuple represents the product, and wherein its elements represent individual properties of the product;
wherein the computer
uses a variator module for varying the material tuple and to vary the operation parameter tuple and to provide tuple variations to the simulator module for performing multiple simulations;
uses an instance classifier module for classifying simulation instances into first class instances that provide product tuples representing products that would be pre-defined products, and second class instances otherwise;
uses an evaluator module for clustering the instances according to attributes of the operation parameter elements and according to the first or second class instances, resulting—for operation parameters separately—
in a first cluster with first class instances and with a first attribute range, and in a second cluster for remaining instances, and with a second attribute range;
uses the evaluator module for identifying at least two parameter values for that the first and second clusters differ with statistical significance;
uses the variator module and the simulator module for repeating the simulation with variations, and identifies the candidate for modification as the at least one parameter that for the simulation represents an alternative process phase of the industrial system that takes in material as an alternative mixture of substances, performs activities of the pre-defined industrial process according to an alternative operation parameter set, and delivers the pre-defined product,
wherein the tuple variator module comprises a material tuple variator module that generates a material variation set by processing historical data to identify value ranges with boundaries for shares of the substances in the mixture and varying elements of the material tuples within boundary elements that correspond to the boundaries,
wherein the material tuple variator module generates the material variation set by processing historical data for historical material variations, wherein particular substances are represented by intervals with minimum and maximum quantities, and
wherein the variator tuple module comprises an operation parameter tuple variator that varies parameter elements for the simulation according to a modification feasibility of the operation parameters.

2. Method according to claim 1, wherein the evaluator module performs the identifying with detecting that the first and the second clusters differ significantly by applying metrics, selected from: cross-referencing, t-testing.

3. Method according to claim 1, wherein the evaluator module determines if the at least two parameter values represent parameters that are related in the industrial system.

4. Method according to claim 3, wherein the evaluator module performs the determining by interacting with a simulation user that is the user of the computer.

5. Method according to claim 1, wherein the material tuple variator module generates the material variation set by generating intermediate values within the intervals, with a value spacing that is larger than the value spacing of the material.

6. Method according to claim 1, wherein the modification feasibility of the operation parameters corresponds to a likelihood by that the candidate for modification can actually turn the original parameter set to the alternative operation parameter set.

7. Method according to claim 1, wherein the computer uses the instance classifier module for classifying simulation instances into first and second class instances by applying further criteria, such as process related criteria.

8. Method according to claim 1, wherein the computer uses the variator module as follows:
before the evaluator module performs clustering, the variator module provides a relatively large number of variations in the material tuple and provides a relatively small number of variations in the operation parameter tuple, and
after the evaluator module performs clustering, the variator module provides a relatively smaller number of variations in the material tuple and a provides a relatively larger number of variations in the operation parameter tuple.

9. Method according to claim 8, wherein—after clustering—the variator module provides the relatively smaller number of variations in the operation parameter tuple as variations of the identified at least two parameter values for that the first and second clusters differ with statistical significance.

10. Method according to claim 9, wherein the variator module provides the relatively small number of variations in the material tuple as the material tuple that corresponds to the standard material in the standard mixture of substances.

11. A computer program product, the computer program product being tangibly embodied on a non-transitory computer-readable storage medium and comprising instructions that, when executed by at least one computing device, are configured to cause the at least one computing device:
to identify an operation parameter of an industrial process as a candidate for a parameter modification,
wherein an industrial system, in a standard process phase, takes in standard material as a standard mixture of substances, performs activities of a pre-defined industrial process according to a plurality of operation parameters, referred to as an original operation parameter set hereinafter, and delivers a product, with the product having pre-defined properties, referred to as a pre-defined product hereinafter;
with a simulator module, to simulate the industrial process by accessing a model that represents the system and that represents the industrial process,
wherein the simulator module in each simulation instance receives a material tuple with elements, wherein the material tuple represents the material, and wherein its elements represent substances of the material,
wherein the simulator module in each simulation instance receives an operation parameter tuple with elements, wherein the operation parameter tuple represents operation parameters set of the industrial process, and wherein its elements represent individual operation parameters as well as their attributes, and
wherein the simulator module in each simulation instance provides a product tuple with elements, wherein the product tuple represents the product, and wherein its elements represent individual properties of the product;
with a variator module, to vary the material tuple and to vary the operation parameter tuple and to provide tuple variations to the simulator module for performing multiple simulations;
with an instance classifier module, to classify simulation instances into first class instances that provide product tuples representing products that would be pre-defined products, and second class instances otherwise;
with an evaluator module, to cluster the instances according to attributes of the operation parameter elements and according to the first or second class instances, resulting—for operation parameters separately—
in a first cluster with first class instances and with a first attribute range, and in a second cluster for remaining instances, and with a second attribute range;
with the evaluator module to identify at least two parameter values for that the first and second clusters differ with statistical significance;
with the variator module and the simulator module, to repeat the simulation with variations, and identify the candidate for modification as the at least one parameter that for the simulation represents an alternative process phase of the industrial system that takes in material as an alternative mixture of substances, and perform activities of the pre-defined industrial process according to an alternative operation parameter set, and deliver the pre-defined product,
wherein the tuple variator module comprises a material tuple variator module that generates a material variation set by processing historical data to identify value ranges with boundaries for shares of the substances in the mixture; and varying elements of the material tuples within boundary elements that correspond to the boundaries,
wherein the material tuple variator module generates the material variation set by processing historical data for historical material variations, wherein particular substances are represented by intervals with minimum and maximum quantities, and wherein the variator tuple module comprises an operation parameter tuple variator that varies parameter elements for the simulation according to a modification feasibility of the operation parameters.

12. The computer program product of claim 11, wherein the instructions, when executed, are further configured to cause the evaluator module to perform the identifying with detecting that the first and the second clusters differ significantly by applying metrics, selected from: cross-referencing, t-testing.

13. The computer program product of claim 11, wherein the instructions, when executed, are further configured to cause the evaluator module to determine if the at least two parameter values represent parameters that are related in the industrial system.

14. The computer program product of claim 13, wherein the instructions, when executed, are further configured to cause the evaluator module to perform the determining by interacting with a simulation user that is the user of the computer.

15. The computer program product of claim 13, wherein the instructions, when executed, are further configured to cause the material tuple variator module to generate the material variation set by generating intermediate values within the intervals, with a value spacing that is larger than the value spacing of the material.

16. A computer system comprising: at least one memory including instructions; and at least one processor that is operably coupled to the at least one memory and that is arranged and configured to execute instructions that, when executed, cause the at least one processor to:
to identify an operation parameter of an industrial process as a candidate for a parameter modification,
wherein an industrial system, in a standard process phase, takes in standard material as a standard mixture of substances, performs activities of a pre-defined industrial process according to a plurality of operation parameters, referred to as an original operation parameter set hereinafter, and delivers a product, with the product having pre-defined properties, referred to as a pre-defined product hereinafter;
with a simulator module, to simulate the industrial process by accessing a model that represents the system and that represents the industrial process,
wherein the simulator module in each simulation instance receives a material tuple with elements, wherein the material tuple represents the material, and wherein its elements represent substances of the material,
wherein the simulator module in each simulation instance receives an operation parameter tuple with elements, wherein the operation parameter tuple represents operation parameters set of the industrial process, and wherein its elements represent individual operation parameters as well as their attributes, and
wherein the simulator module in each simulation instance provides a product tuple with elements, wherein the product tuple represents the product, and wherein its elements represent individual properties of the product;
with a variator module, to vary the material tuple and to vary the operation parameter tuple and to provide tuple variations to the simulator module for performing multiple simulations;
with an instance classifier module, to classify simulation instances into first class instances that provide product tuples representing products that would be pre-defined products, and second class instances otherwise;
with an evaluator module, to cluster the instances according to attributes of the operation parameter elements and according to the first or second class instances, resulting—for operation parameters separately—
in a first cluster with first class instances and with a first attribute range, and in a second cluster for remaining instances, and with a second attribute range;
with the evaluator module to identify at least two parameter values for that the first and second clusters differ with statistical significance;
with the variator module and the simulator module, to repeat the simulation with variations, and identify the candidate for modification as the at least one parameter that for the simulation represents an alternative process phase of the industrial system that takes in material as an alternative mixture of substances, and perform activities of the pre-defined industrial process according to an alternative operation parameter set, and deliver the pre-defined product,
wherein the tuple variator module comprises a material tuple variator module that generates a material variation set by processing historical data to identify value ranges with boundaries for shares of the substances in the mixture; and varying elements of the material tuples within boundary elements that correspond to the boundaries,
wherein the material tuple variator module generates the material variation set by processing historical data for historical material variations, wherein particular substances are represented by intervals with minimum and maximum quantities, and wherein the variator tuple module comprises an operation parameter tuple variator that varies parameter elements for the simulation according to a modification feasibility of the operation parameters.

17. The computer system of claim 16, wherein the instructions, when executed, are further configured to cause the evaluator module to perform the identifying with detecting that the first and the second clusters differ significantly by applying metrics, selected from: cross-referencing, t-testing.

18. The computer system of claim 16, wherein the instructions, when executed, are further configured to cause the evaluator module to determine if the at least two parameter values represent parameters that are related in the industrial system.

19. The computer system of claim 18, wherein the instructions, when executed, are further configured to cause the evaluator module to perform the determining by interacting with a simulation user that is the user of the computer.

20. The computer system of claim 18, wherein the instructions, when executed, are further configured to cause the material tuple variator module to generate the material variation set by generating intermediate values within the intervals, with a value spacing that is larger than the value spacing of the material.
